(19) United States
(12) Patent Application Publication
(10) Pub. No.: US 2023/0095830 A1
(43) Pub. Date: Mar. 30, 2023

(54) THREE-DIMENSIONAL SEMICONDUCTOR DEVICE AND METHOD OF FABRICATING THE SAME

(71) Applicant: Samsung Electronics Co., Ltd., Suwon-si (KR)

(72) Inventors: Hyo-Jin KIM, Bucheon-si (KR); Daewon HA, Seoul (KR)

(73) Assignee: Samsung Electronics Co., Ltd., Suwon-si (KR)

(21) Appl. No.: 17/834,240

(22) Filed: Jun. 7, 2022

(30) Foreign Application Priority Data
Sep. 27, 2021 (KR) 10-2021-0127028

(51) Int. Cl. H01L 29/78; H01L 29/417

(52) U.S. Cl. CPC H01L 29/7804; H01L 29/41775; H01L 29/41791; H01L 29/41766

(57) ABSTRACT

Disclosed are three-dimensional semiconductor device and their fabrication methods. The device includes a first active region on a substrate and including a first source/drain pattern and a first channel pattern connected to the first source/drain pattern, a first active contact on the first source/drain pattern, a second active region on the first active region and the first active contact and including a second source/drain pattern and a second channel pattern connected to the second source/drain pattern, a second active contact on the second source/drain pattern, a gate electrode that vertically extends from the first channel pattern toward the second channel pattern, a first power line and a second power line that are below the first active region, and a first metal layer on the gate electrode and the second active contact.

### CROSS-REFERENCE TO RELATED APPLICATION

This U.S. nonprovisional application claims priority under 35 U.S.C § 119 to Korean Patent Application No. 10-2021-0127028 filed on Sep. 27, 2021 in the Korean Intellectual Property Office, the disclosure of which is hereby incorporated by reference in its entirety.

### BACKGROUND

The present inventive concepts relate to three-dimensional semiconductor devices and/or methods of fabricating the same, and more particularly, to three-dimensional semiconductor devices including a field effect transistor and/or methods of fabricating the same.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Some example embodiments of the present inventive concepts provide three-dimensional semiconductor devices with increased integration.

Some example embodiments of the present inventive concepts provide methods of fabricating a semiconductor device with increased integration.

According to some example embodiments of the present inventive concepts, a three-dimensional semiconductor device may include a first active region on a substrate, the first active region including a first source/drain pattern and a first channel pattern connected to the first source/drain pattern; a first active contact on the first source/drain pattern; a second active region on the first active region and the first active contact, the second active region including a second source/drain pattern and a second channel pattern connected to the second source/drain pattern; a second active contact on the second source/drain pattern; a gate electrode that vertically extends from the first channel pattern toward the second channel pattern; a first power line and a second power line that are below the first active region; and a first metal layer on the gate electrode and the second active contact. The first active contact may include a first connection part connected to the first source/drain pattern; and a first pad part that horizontally extends from the first connection part. The second active contact may include a second connection part connected to the second source/drain pattern; and a second pad part that horizontally extends from the second connection part. The first pad part may be horizontally offset from the second active contact. The second pad part may be horizontally offset from the first active contact. The first pad part may be electrically connected through a first via to one of the first power line and a first wiring line in the first metal layer. The second pad part may be electrically connected through a second via to one of the second power line and a second wiring line in the first metal layer.

According to some example embodiments of the present inventive concepts, a three-dimensional semiconductor device may include a first active region on a substrate, the first active region including a first source/drain pattern and a first channel pattern connected to the first source/drain pattern; a first active contact on the first source/drain pattern; a second active region on the first active region and the first active contact, the second active region including a second source/drain pattern and a second channel pattern connected to the second source/drain pattern; a second active contact on the second source/drain pattern, the second active contact includes a first part that vertically overlaps the first active contact and a second part that does not vertically overlap the first active contact; a gate electrode that vertically extends from the first channel pattern toward the second channel pattern; a power line below the first active region; a first metal layer on the gate electrode and the second active contact; and a lower via on a bottom surface of the second part, the lower via electrically connecting the second part to the power line. The lower via may be spaced apart from a sidewall of the first active contact.

According to some example embodiments of the present inventive concepts, a three-dimensional semiconductor device may include a device isolation layer on a substrate; a first power line and a second power line that are buried in the device isolation layer; a first active region on the device isolation layer, the first active region including a first source/drain pattern and a first channel pattern connected to the first source/drain pattern; a first active contact on the first source/drain pattern; a second active region on the first active region and the first active contact, the second active region including a second source/drain pattern and a second channel pattern connected to the second source/drain pattern; a second active contact on the second source/drain pattern; a gate electrode that vertically extends from the first channel pattern toward the second channel pattern; a first gate cutting pattern and a second gate cutting pattern on opposite ends of the gate electrode; and a first metal layer on the gate electrode and the second active contact. The first and second gate cutting patterns may vertically overlap the first and second power lines.

### BRIEF DESCRIPTION OF THE DRAWINGS

FIG. 1 illustrates a conceptual diagram showing a logic cell of a semiconductor device according to a comparative example of the present inventive concepts.

FIG. 2 illustrates a conceptual view showing a semiconductor device according to some example embodiments of the present inventive concepts.

FIG. 3 illustrates a plan view showing a three-dimensional semiconductor device according to some example embodiments of the present inventive concepts.

FIGS. 4A, 4B, 4C, and 4D illustrate cross-sectional views respectively taken along lines A-A′, B-B′, C-C′, and D-D′ of FIG. 3.

FIGS. 5 and 6 illustrate cross-sectional views taken along line C-C′ of FIG. 3, showing a semiconductor device according to some example embodiments of the present inventive concepts.

FIGS. 7A to 16C illustrate cross-sectional views showing a method of fabricating a semiconductor device according to some example embodiments of the present inventive concepts.

FIGS. 17A, 17B, 17C, and 17D illustrate cross-sectional views respectively taken along lines A-A′, B-B′, C-C′, and D-D′ of FIG. 3, showing a semiconductor device according to some example embodiments of the present inventive concepts.

FIG. 18 illustrates a cross-sectional view taken along line B-B′ of FIG. 3, showing a semiconductor device according to some example embodiments of the present inventive concepts.

FIG. 19 illustrates a cross-sectional view taken along line C-C′ of FIG. 3, showing a semiconductor device according to some example embodiments of the present inventive concepts.

### DETAILED DESCRIPTION OF EMBODIMENTS

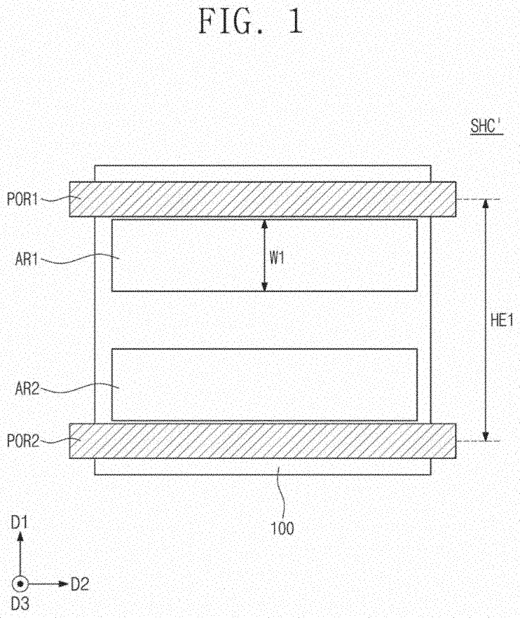

FIG. 1 illustrates a conceptual diagram showing a logic cell of a semiconductor device according to a comparative example of the present inventive concepts. FIG. 1 shows a logic cell of a two-dimensional device according to a comparative example of the present inventive concepts.

Referring to FIG. 1, a single height cell SHC′ may be provided. For example, a substrate 100 may be provided thereon with a first power line POR1 and a second power line POR2. One of the first and second power lines POR1 and POR2 may be provided with a drain voltage (VDD) or a power voltage. The other of the first and second power lines POR1 and POR2 may be provided with a source voltage (VSS) or a ground voltage. For example, the source voltage (VSS) may be applied to the first power line POR1, and the drain voltage (VDD) may be applied to the second power line POR2.

The single height cell SHC′ may be defined between the first power line POR1 and the second power line POR2. The single height cell SHC′ may include a first active region AR1 and a second active region AR2. One of the first and second active regions AR1 and AR2 may be a PMOSFET region, and the other of the first and second active regions AR1 and AR2 may be an NMOSFET region. For example, the first active region AR1 may be an NMOSFET region, and the second active region AR2 may be a PMOSFET region. For example, the single height cell SHC′ may have a complementary metal oxide semiconductor (CMOS) structure provided between the first power line POR1 and the second power line POR2.

A semiconductor device according to a comparative example may be a two-dimensional device in which transistors of a front-end-of-line (FEOL) layer are arranged two-dimensionally. For example, NMOSFETs on the first active region AR1 may be formed spaced apart in a first direction D1 from PMOSFETs on the second active region AR2.

Each of the first and second active regions AR1 and AR2 may have a first width W1 in the first direction D1. A first height HE1 may be defined to indicate a length in the first direction D1 of the single height cell SHC′ according to a comparative example. The first height HE1 may be substantially the same as a distance (e.g., pitch) between the first power line POR1 and the second power line POR2.

The single height cell SHC′ may constitute a single logic cell. In this description, the logic cell may mean a logic device, such as AND, OR, XOR, XNOR, and inverter, that performs a specific function. For example, the logic cell may include transistors for constituting a logic device and wiring lines that connect the transistors to each other.

Because a two-dimensional device is included in the single height cell SHC′ according to a comparative example, the first active region AR1 and the second active region AR2 may be disposed spaced apart from each other in the first direction D1 without overlapping each other. Therefore, it may be required that the first height HE1 of the single height cell SHC′ be defined to include all of the first and second active regions AR1 and AR2 that are spaced apart from each other in the first direction D1. As a result, the first height HE1 of the single height cell SHC′ according to a comparative example may be required to become relatively large. Therefore, the single height cell SHC′ according to a comparative example may have a relatively large area.

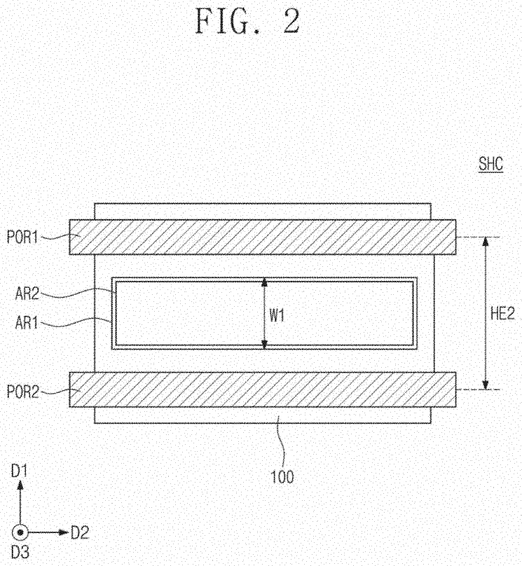

FIG. 2 illustrates a conceptual view showing a semiconductor device according to some example embodiments of the present inventive concepts. FIG. 2 depicts a logic cell of a three-dimensional device according to some example embodiments of the present inventive concepts.

Referring to FIG. 2, a single height cell SHC may be provided which includes a three-dimensional device such as a stacked transistor. For example, a substrate 100 may be provided thereon with a first power line POR1 and a second power line POR2. The single height cell SHC may be defined between the first power line POR1 and the second power line POR2.

The single height cell SHC may include a first active region AR1 and a second active region AR2. One of the first and second active regions AR1 and AR2 may be a PMOSFET region, and the other of the first and second active regions AR1 and AR2 may be an NMOSFET region.

A semiconductor device according to some example embodiments may be a three-dimensional device in which transistors of a front-end-of-line (FEOL) layer are stacked vertically. The substrate 100 may be provided thereon with the first active region AR1 as a bottom tier, and the first active region AR1 may be provided thereon with the second active region AR2 as a top tier. For example, NMOSFETs of the first active region AR1 may be provided on the substrate 100, and PMOSFETs of the second active region AR2 may be stacked on the NMOSFETs. The first active region AR1 and the second active region AR2 may be spaced apart from each other in a vertical direction or a third direction D3.

Each of the first and second active regions AR1 and AR2 may have a first width W1 in the first direction D1. A second height HE2 may be defined to indicate a length in the first direction D1 of the single height cell SHC according to some example embodiments.

Because the single height cell SHC according to some example embodiments includes a three-dimensional device or a stacked transistor, the first active region AR1 and the second active region AR2 may overlap each other. Therefore, the second height HE2 of the single height cell SHC may have a size enough to have the first width W1. As a result, the second height HE2 of the single height cell SHC according to some example embodiments may be less that the first height HE1 of the single height cell SHC′ discussed above in FIG. 1. For example, the single height cell SHC according to some example embodiments may have a relatively small area. For a three-dimensional semiconductor device according to some example embodiments, an area of a logic cell may be reduced to increase integration of the device.

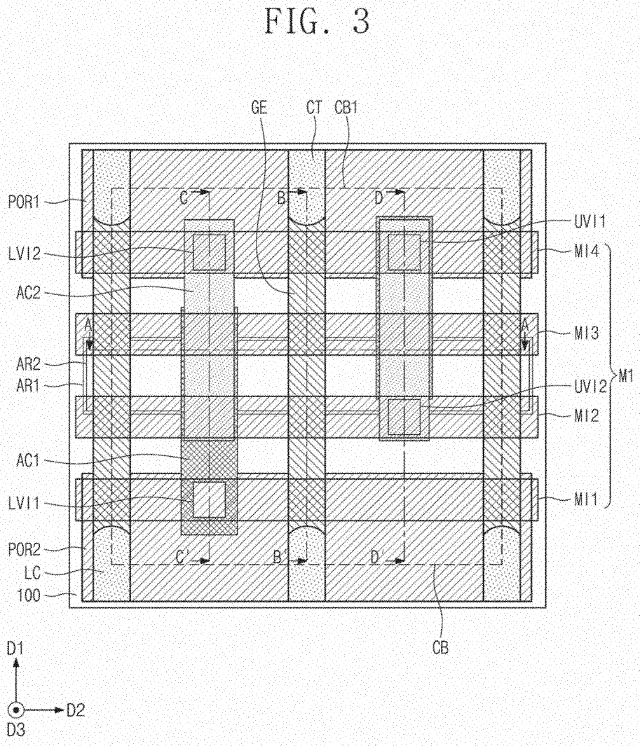

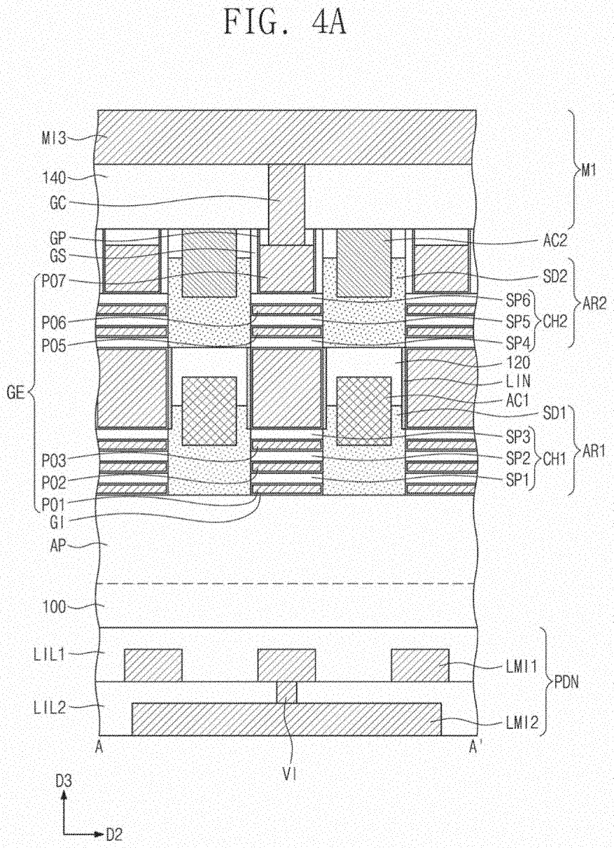

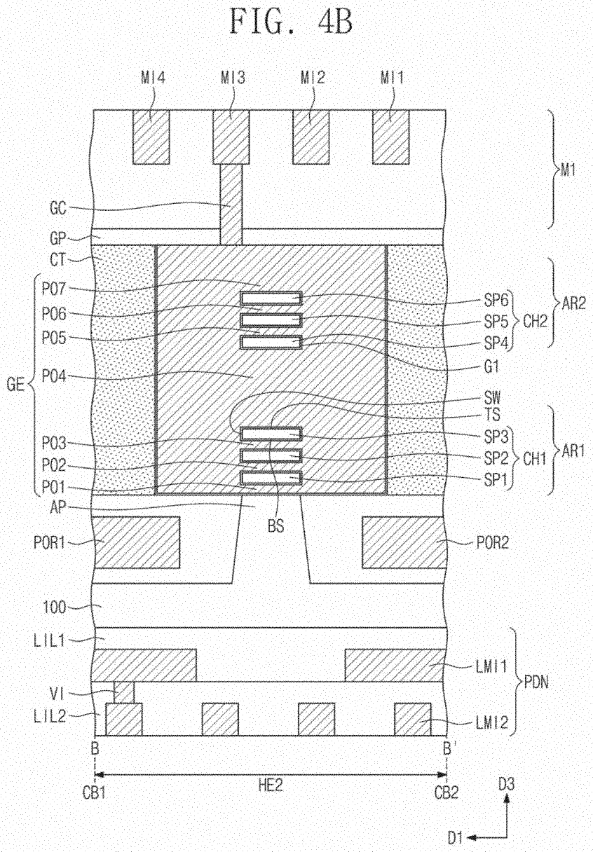

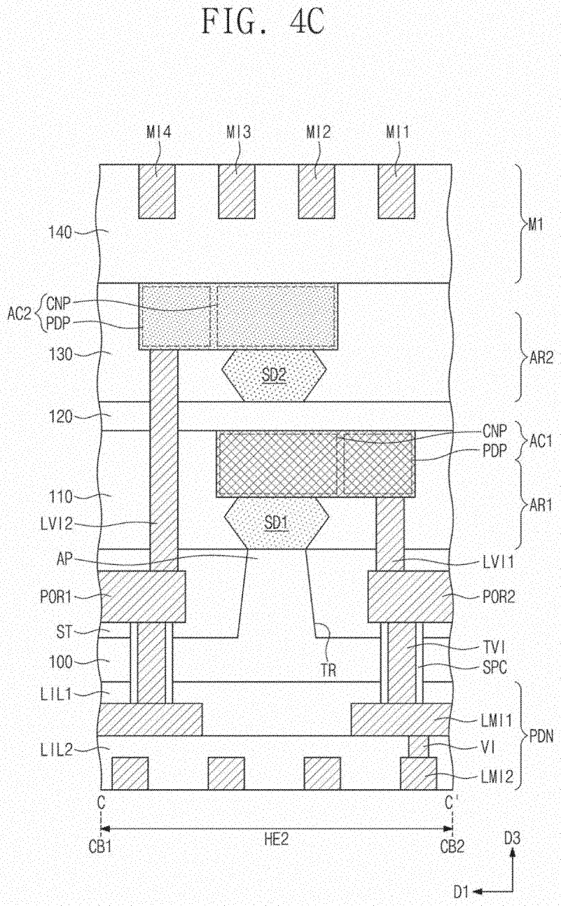

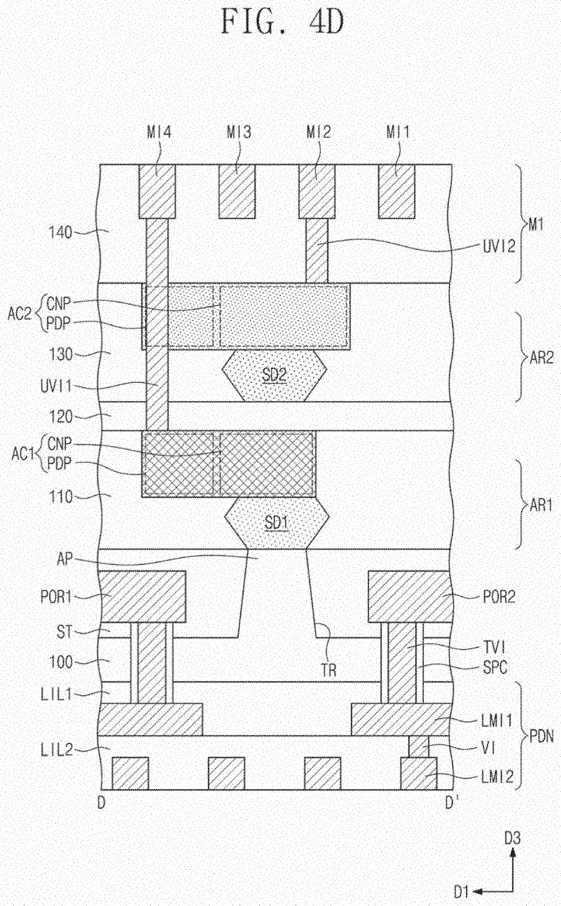

FIG. 3 illustrates a plan view showing a three-dimensional semiconductor device according to some example embodiments of the present inventive concepts. FIGS. 4A, 4B, 4C, and 4D illustrate cross-sectional views respectively taken along lines A-A′, B-B′, C-C′, and D-D′ of FIG. 3. A three-dimensional semiconductor device shown in FIGS. 3 and 4A to 4D may be a detailed example of the single height cell SHC illustrated in FIG. 2.

Referring to FIGS. 3 and 4A to 4D, a logic cell LC may be provided on a substrate 100. For example, the logic cell LC according to some example embodiments may be an inverter cell. The substrate 100 may be a compound semiconductor substrate or a semiconductor substrate including silicon, germanium, or silicon-germanium. For example, the substrate 100 may be a silicon substrate.

The logic cell LC may include a first active region AR1 and a second active region AR2 that are sequentially stacked on the substrate 100. One of the first and second active regions AR1 and AR2 may be a PMOSFET region, and the other of the first and second active regions AR1 and AR2 may be an NMOSFET region. The first active region AR1 may be provided on a bottom tier of a front-end-of-line (FEOL) layer, and the second active region AR2 may be provided on a top tier of a front-end-of-line (FEOL) layer. PMOS and NMOS field effect transistors of the first and second active regions AR1 and AR2 may be vertically stacked to constitute a three-dimensional stacked transistor.

The PMOS and NMOS field effect transistors of the first and second active regions AR1 and AR2 may be logic transistors included in a logic circuit. In some example embodiments of the present inventive concepts, an inverter may be constituted by the PMOS and NMOS field effect transistors of the first and second active regions AR1 and AR2. When viewed in plan, the stacked first and second active regions AR1 and AR2 may be positioned between a first power line POR1 and a second power line POR2.

An active pattern AP may be defined by a trench TR formed on an upper portion of the substrate 100. The active pattern AP may be a vertically protruding portion of the substrate 100. When viewed in plan, the active pattern AP may have a bar shape that extends in a second direction D2. The active pattern AP may be provided thereon with the first and second active regions AR1 and AR2 that are sequentially stacked.

The trench TR may be filled with a device isolation layer ST. The device isolation layer ST may include a silicon oxide layer. The device isolation layer ST may have a top surface the same as or lower than that of a top surface of the active pattern AP. The device isolation layer ST may not cover any of first and second channel patterns CH1 and CH2 which will be discussed below.

The active pattern AP may be provided thereon with the first active region AR1 that includes first channel patterns CH1 and first source/drain patterns SD1. Each of the first channel patterns CH1 may be interposed between a pair of first source/drain patterns SD1. The first channel pattern CH1 may connect the pair of first source/drain patterns SD1 to each other.

The first channel pattern CH1 may include a first semiconductor pattern SP1, a second semiconductor pattern SP2, and a third semiconductor pattern SP3 that are sequentially staked. The first, second, and third semiconductor patterns SP1, SP2, and SP3 may be spaced apart from each other in a vertical direction or a third direction D3. The first, second, and third semiconductor patterns SP1, SP2, and SP3 may include one or more of silicon (Si), germanium (Ge), and silicon-germanium (SiGe). For example, each of the first, second, and third semiconductor patterns SP1, SP2, and SP3 may include crystalline silicon.

The first source/drain patterns SD1 may be provided on the top surface of the active pattern AP. The first source/drain patterns SD1 may be epitaxial patterns formed by a selective epitaxial growth process. For example, the first source/drain pattern SD1 may have a top surface higher than a top surface of the third semiconductor pattern SP3 included in the first channel pattern CH1.

The first source/drain patterns SD1 may be doped with impurities to have a first conductivity type. The first conductivity type may be p-type or n-type. When the first conductivity type is p-type, a transistor of the first active region AR1 may be a PMOSFET. When the first conductivity type is n-type, a transistor of the first active region AR1 may be an NMOSFET. The first source/drain patterns SD1 may include one or more of silicon-germanium (SiGe) and silicon (Si).

First active contacts AC1 may be correspondingly provided on the first source/drain patterns SD1. The first active contacts AC1 may be provided on a bottom tier of a front-end-of-line (FEOL) layer. Each of the first active contacts AC1 may have a linear shape that extends in a first direction D1. The first active contact AC1 may be electrically connected to the first source/drain pattern SD1. In some example embodiments, the first active contact AC1 may be provided in a recess formed on an upper portion of the first source/drain pattern SD1 (see FIG. 4A).

For example, the first active contact AC1 may include one or more of doped semiconductor and metal. The metal may include at least one selected from copper (Cu), aluminum (Al), ruthenium (Ru), cobalt (Co), tungsten (W), and molybdenum (Mo).

A first interlayer dielectric layer 110 may be provided on the first source/drain patterns SD1. The first interlayer dielectric layer 110 may cover the first active contacts AC1. For example, each of the first active contacts AC1 may have a top surface coplanar with that of the first interlayer dielectric layer 110. A second interlayer dielectric layer 120 may be provided on the first interlayer dielectric layer 110. The second interlayer dielectric layer 120 may cover the top surface of the first interlayer dielectric layer 110.

The second active region AR2 may be provided on the second interlayer dielectric layer 120. The second interlayer dielectric layer 120 may be interposed between the first active region AR1 and the second active region AR2. For example, the second interlayer dielectric layer 120 may vertically separate the first active region AR1 from the second active region AR2.

The second active region AR2 may include second channel patterns CH2 and second source/drain patterns SD2. The second channel patterns CH2 may correspondingly and vertically overlap the first channel patterns CH1. The second source/drain patterns SD2 may correspondingly and vertically overlap the first source/drain patterns SD1. Each of the second channel patterns CH2 may be interposed between a pair of second source/drain patterns SD2. The second channel pattern CH2 may connect the pair of second source/drain patterns SD2 to each other.

The second channel pattern CH2 may include a fourth semiconductor pattern SP4, a fifth semiconductor pattern SP5, and a sixth semiconductor pattern SP6 that are sequentially stacked. The fourth, fifth, and sixth semiconductor patterns SP4, SP5, and SP6 may be spaced apart from each other in the third direction D3. The fourth, fifth, and sixth semiconductor patterns SP4, SP5, and SP6 of the second channel pattern CH2 may include the same semiconductor material as that of the first, second, and third semiconductor patterns SP1, SP2, and SP3 of the first channel pattern CH1.

The second source/drain patterns SD2 may be provided on a top surface of the second interlayer dielectric layer 120. The second source/drain patterns SD2 may be epitaxial patterns formed by a selective epitaxial growth process. For example, the second source/drain pattern SD2 may have a top surface higher than that of the sixth semiconductor pattern SP6 included in the second channel pattern CH2.

The second source/drain patterns SD2 may be doped with impurities to have a second conductivity type. The second conductivity type may be different from the first conductivity type of the first source/drain pattern SD1. The second source/drain patterns SD2 may include one or more of silicon-germanium (SiGe) and silicon (Si).

Second active contacts AC2 may be correspondingly provided on the second source/drain patterns SD2. The second active contacts AC2 may be provided on a top tier of a front-end-of-line (FEOL) layer. Each of the second active contacts AC2 may have a linear shape that extends in the first direction D1. The second active contact AC2 may be electrically connected to the second source/drain pattern SD2. In some example embodiments, the second active contact AC2 may be provided in a recess formed on an upper portion of the second source/drain pattern SD2 (see FIG. 4A). For example, the second active contact AC2 may include the same material as that of the first active contact AC1.

A third interlayer dielectric layer 130 may be provided on the second source/drain patterns SD2. The third interlayer dielectric layer 130 may cover the second active contacts AC2. For example, each of the second contacts AC2 may have a top surface coplanar with that of the third interlayer dielectric layer 130.

A gate electrode GE may be provided on the stacked first and second channel patterns CH1 and CH2. When viewed in plan, the gate electrode GE may have a bar shape that extends in the first direction D1. A plurality of gate electrodes GE may be provided on the substrate 100, and the gate electrodes GE may be arranged along the second direction D2 at a first pitch. The gate electrodes GE may vertically overlap the stacked first and second channel patterns CH1 and CH2.

Referring back to FIG. 4B, the gate electrode GE may extend in a vertical direction (e.g., the third direction D3) to a gate capping pattern GP, which will be discussed below, from the top surface of the device isolation layer ST (or from the top surface of the active pattern AP). The gate electrodes GE may extend in the third direction D3 from the first channel pattern CH1 of the first active region AR1 to the second channel pattern CH2 of the second active region AR2. The gate electrode GE may extend in the third direction D3 from the first semiconductor pattern SP1 at a lowermost position to the sixth semiconductor pattern SP6 at an uppermost position.

The gate electrode GE may include a first part PO1 interposed between the active pattern AP and the first semiconductor pattern SP1, a second part PO2 interposed between the first semiconductor pattern SP1 and the second semiconductor pattern SP2, a third part PO3 interposed between the second semiconductor pattern SP2 and the third semiconductor pattern SP3, a fourth part PO4 interposed between the third semiconductor pattern SP3 and the fourth semiconductor pattern SP4, a fifth part PO5 interposed between the fourth semiconductor pattern SP4 and the fifth semiconductor pattern SP5, a sixth part PO6 interposed between the fifth semiconductor pattern SP5 and the sixth semiconductor pattern SP6, and a seventh part PO7 on the sixth semiconductor pattern SP6. A length in the third direction D3 of each of the fourth and seventh parts PO4 and PO7 may be greater than a length in the third direction D3 of each of the first, second, third, fifth, and sixth parts PO1, PO2, PO3, PO5, and PO6.

The gate electrode GE may be provided on a top surface TS, a bottom surface BS, and opposite sidewalls SW of each of the first to sixth semiconductor patterns SP1 to SP6. In this sense, a transistor according to some example embodiments may be a three-dimensional field effect transistor (e.g., MBCFET or GAAFET) in which the gate electrode GE three-dimensionally surrounds the first and second channel patterns CH1 and CH2.

Referring back to FIGS. 3 and 4A to 4D, a pair of gate spacers GS may be disposed on opposite sidewalls of the seventh part PO7 of the gate electrode GE. The gate spacers GS may extend in the first direction D1 along the gate electrode GE. The gate spacers GS may have their top surfaces higher than that of the gate electrode GE. The top surfaces of the gate spacers GS may be coplanar with the top surface of the first interlayer dielectric layer 110. The gate spacers GS may include at least one selected from SiCN, SiCON, and SiN. Alternatively, the gate spacers GS may each include a multiple layer formed of at least two selected from SiCN, SiCON, and SiN. A pair of liner layers LIN may be provided on opposite sidewalls of the fourth part PO4 of the gate electrode GE.

A gate capping pattern GP may be provided on the gate electrode GE. The gate capping pattern GP may extend in the first direction D1 along the gate electrode GE. In detail, the gate capping pattern GP may include at least one selected from SiON, SiCN, SiCON, and SiN.

A gate dielectric layer GI may be interposed between the gate electrode GE and each of the first to sixth semiconductor patterns SP1 to SP6. The gate dielectric layer GI may cover the top surface TS, the bottom surface BS, and the opposite sidewalls SW of each of the first to sixth semiconductor patterns SP1 to SP6. The gate dielectric layer GI may cover the top surface of the device isolation layer ST below the gate electrode GE (see FIG. 4B).

In some example embodiments of the present inventive concepts, the gate dielectric layer GI may include one or more of a silicon oxide layer, a silicon oxynitride layer, and a high-k dielectric layer. The high-k dielectric layer may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Alternatively, a semiconductor device according to the present inventive concepts may include a negative capacitance field effect transistor that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about or exactly 60 mV/decade at room temperature (e.g., about or exactly, 20° C., 22° C., or 20-22° C.).

The ferroelectric material layer may have ferroelectric properties. The ferroelectric material layer may include, for example, one or more of hafnium oxide, hafnium zirconium oxide, barium strontium titanium oxide, and lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on what ferroelectric material is included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

When the impurities are aluminum (Al), the ferroelectric material layer may include about or exactly 3 to 8 atomic percent aluminum. In this description, the ratio of impurities may be a ratio of aluminum to the sum of hafnium and aluminum.

When the impurities are silicon (Si), the ferroelectric material layer may include about or exactly 2 to about or exactly 10 atomic percent silicon. When the impurities are yttrium (Y), the ferroelectric material layer may include about or exactly 2 to about or exactly 10 atomic percent yttrium. When the impurities are gadolinium (Gd), the ferroelectric material layer may include about or exactly 1 to about or exactly 7 atomic percent gadolinium. When the impurities are zirconium (Zr), the ferroelectric material layer may include about or exactly 50 to about or exactly 80 atomic percent zirconium.

The paraelectric material layer may have paraelectric properties. The paraelectric material layer may include, for example, at least one selected from silicon oxide and high-k metal oxide. The metal oxide included in the paraelectric material layer may include, for example, at least one selected from hafnium oxide, zirconium oxide, and aluminum oxide, but the present inventive concepts are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about or exactly 0.5 nm to about or exactly 10 nm, but the present inventive concepts are not limited thereto. Because ferroelectric materials have their own critical thickness that exhibits ferroelectric properties, the thickness of the ferroelectric material layer may depend on ferroelectric material.

For example, the gate dielectric layer GI may include a single ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

The gate electrode GE may include a first metal pattern and a second metal pattern on the first metal pattern. The first metal pattern may be provided on the gate dielectric layer GI and adjacent to the first to sixth semiconductor patterns SP1 to SP6.

The first metal pattern may include a work-function metal that controls a threshold voltage of a transistor. A thickness and composition of the first metal pattern may be adjusted to achieve a desired threshold voltage of a transistor. For example, the first, second, third, fifth, and sixth parts PO1, PO2, PO3, PO5, and PO6 of the gate electrode GE may be formed of the first metal pattern or work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta). For example, the fourth and seventh parts PO4 and PO7 of the gate electrode GE may include a first metal pattern and a second metal pattern on the first metal pattern.

Referring to FIG. 3, the logic cell LC may include a first cell boundary CB1 that extends in the second direction D2. On a location opposite to that of the first cell boundary CB1, a second cell boundary CB2 may be defined to extend in the second direction D2. Gate cutting patterns CT may be disposed on the first and second cell boundaries CB1 and CB2 of the logic cell LC. When viewed in plan, the gate cutting patterns CT may be arranged at a first pitch along the first cell boundary CB1. The gate cutting patterns CT may be arranged at the first pitch along the second cell boundary CB2. When viewed in plan, the gate cutting patterns CT on the first and second cell boundaries CB1 and CB2 may be disposed to correspondingly overlap the gate electrodes GE.

The gate cutting pattern CT may penetrate the gate electrode GE. The gate cutting pattern CT may separate the gate electrode GE from another gate electrode that is adjacent to the gate electrode GE. For example, referring to FIG. 4B, a pair of gate cutting patterns CT may be provided on opposite ends of the gate electrode GE. The gate cutting patterns CT may include a dielectric material, such as a silicon oxide layer, a silicon nitride layer, or a combination thereof.

When viewed in plan, the first power line POR1 may be provided on the first cell boundary CB1, the second power line POR2 may be provided on the second cell boundary CB2. The gate cutting patterns CT may vertically overlap the first and second power lines POR1 and POR2. A drain voltage (VDD) may be applied to one of the first power line POR1 and the second power line POR2, and a source voltage (VSS) may be applied to the other of the first power line POR1 and the second power line POR2.

The first and second power lines POR1 and POR2 may be buried in the device isolation layer ST. The active pattern AP may be disposed between and horizontally spaced apart from the first and second power lines POR1 and POR2.

The first and second power lines POR1 and POR2 may each have a linear shape that extends in the second direction D2 in the device isolation layer ST. The first and second power lines POR1 and POR2 may extend along the second direction D2 along the first and second cell boundaries CB1 and CB2.

A power delivery network PDN may be provided on a bottom surface of the substrate 100. The power delivery network PDN may include a first lower dielectric layer LIL1 and a second lower dielectric layer LIL2 that are sequentially stacked on the bottom surface of the substrate 100.

The power delivery network PDN may further include first lower lines LMI1 and second lower lines LMI2. The first lower lines LMI1 may be provided in the first lower dielectric layer LILT, and the second lower lines LMI2 may be provided in the second lower dielectric layer LIL2. A via VI may be provided between the first lower line LMI1 and the second lower line LMI2. A via VI may be provided between the first lower line LMI1 and the second lower line LMI2. The first and second lower lines LMI1 and LMI2 and the vias VI may include metal selected from copper (Cu), aluminum (Al), ruthenium (Ru), cobalt (Co), tungsten (W), and molybdenum (Mo).

Through vias TVI may be provided between the power delivery network PDN below the substrate 100 and the first and second power lines POR1 and POR2 on above the substrate 100. The through via TVI may have a pillar shape that extends in the third direction D3 while penetrating the substrate 100. A dielectric spacer SPC may be provided on an outer sidewall of the through via TVI. The dielectric spacer SPC may insulate the through via TVI from the substrate 100.

The through via TVI may extend from the first lower line LMI1 to its corresponding one of the first and second power lines POR1 and POR2. The through vias TVI may electrically connect the first and second power lines POR1 and POR2 to the power delivery network PDN. The through via TVI may include metal selected from copper (Cu), aluminum (Al), ruthenium (Ru), cobalt (Co), tungsten (W), and molybdenum (Mo).

The first and second lower lines LMI1 and LMI2 of the power delivery network PDN may constitute a wiring network for applying the drain voltage (VDD) and the source voltage (VSS) to the first and second power lines POR1 and POR2 of the logic cell LC. Although not shown, the power delivery network PDN may further include a plurality of wiring layers that are stacked on the second lower lines LMI2.

A fourth interlayer dielectric layer 140 may be provided on the third interlayer dielectric layer 130. A first metal layer M1 may be provided in the fourth interlayer dielectric layer 140. The first metal layer M1 on the logic cell LC may include first to fourth wiring lines MI1 to MI4.

The first to fourth wiring lines MI1 to MI4 may parallel extend in the second direction D2 on the logic cell LC. Each of the first to fourth wiring lines MI1 to MI4 may have a linear or bar shape that extends in the second direction D2. The first wiring line MI1 may vertically overlap the first power line POR1, and the fourth wiring line MI4 may vertically overlap the second power line POR2.

The first to fourth wiring lines MI1 to MI4 may be arranged at a second pitch along the first direction D1. For example, the second pitch between the first to fourth wiring lines MI1 to MI4 may be less than the first pitch between the gate electrodes GE. The first to fourth wiring lines MI1 to MI4 may include metal selected from copper (Cu), aluminum (Al), ruthenium (Ru), cobalt (Co), tungsten (W), and molybdenum (Mo).

A gate contact GC may be provided to penetrate the fourth interlayer dielectric layer 140 and the gate capping pattern GP and to electrically connect to the gate electrode GE. For example, the gate contact GC may electrically connect the third wiring line MI3 to the gate electrode GE. The gate contact GC may include metal selected from copper (Cu), aluminum (Al), ruthenium (Ru), cobalt (Co), tungsten (W), and molybdenum (Mo).

The first active contact AC1 may be electrically connected to the second power line POR2 below the first active region AR1 and to at least one selected from the first to fourth wiring lines MI1 to MI4. The second active contact AC2 may be electrically connected to the first power line POR1 below the first active region AR1 and to at least one selected from the first to fourth wiring lines MI1 to MI4.

Referring back to FIG. 4C, the first active contact AC1 may include a connection part CNP connected to the first source/drain pattern SD1 and a pad part PDP that horizontally extends from the connection part CNP. A first lower via LVI1 may be provided on a bottom surface of the pad part PDP included in the first active contact AC1. The first lower via LVI1 may electrically connect the second power line POR2 to the first active contact AC1.

The second active contact AC2 may include a connection part CNP connected to the second source/drain pattern SD2 and a pad part PDP that horizontally extends from the connection part CNP. A second lower via LVI2 may be provided on a bottom surface of the pad part PDP included in the second active contact AC2. The second lower via LVI2 may electrically connect the first power line POR1 to the second active contact AC2.

The connection part CNP of the first active contact AC1 may vertically connect the first source/drain pattern SD1. The connection part CNP of the second active contact AC2 may vertically overlap the second source/drain pattern SD2. The connection part CNP of the first active contact AC1 may vertically overlap the connection part CNP of the second active contact AC2.

When viewed in plan, the pad part PDP of the first active contact AC1 may be horizontally offset from the second active contact AC2. The pad part PDP of the second active contact AC2 may be horizontally offset from the first active contact AC1. Therefore, the second lower via LVI2 may be spaced apart from a sidewall of the first active contact AC1 without being in contact with the first active contact AC1.

According to some example embodiments of the present inventive concepts, even though the second active contact AC2 is stacked on the first active contact AC1, it may be possible to stagger the pad parts PDP of the first and second active contacts AC1 and AC2. The non-overlapped pad parts PDP of the first and second active contacts AC1 and AC2 may be used to electrically connect the first and second active contacts AC1 and AC2 to their target wiring lines. As a result, the present inventive concepts may achieve a three-dimensional cell structure including stacked NMOS and PMOS field effect transistors.

Referring back to FIG. 4D, a first upper via UVI1 may be provided on a top surface of the pad part PDP included in the first active contact AC1. The first upper via UVI1 may vertically extend to the fourth wiring line MI4 from the top surface of the pad part PDP included in the first active contact AC1. The pad part PDP of the second active contact AC2 may vertically overlap the pad part PDP of the first active contact AC1. Therefore, the first upper via UVI1 may penetrate the pad part PDP of the first active contact AC1 to extend to the fourth wiring line MI4. The first upper via UVI1 may electrically connect to each other the first active contact AC1, the second active contact AC2, and the fourth wiring line MI4.

A second upper via UVI2 may be provided on a top surface of the connection part CNP included in the second active contact AC2. The second upper via UVI2 may vertically extend to the second wiring line MI2 from the top surface of the connection part CNP included in the second active contact AC2.

According to some example embodiments of the present inventive concepts, the pad parts PDP of the first and second active contacts AC1 and AC2 may overlap each other, and the first and second active contacts AC1 and AC2 may be vertically connected to each other through an upper via that penetrates the pad parts PDP of the first and second active contacts AC1 and AC2. Therefore, the second source/drain pattern SD2 at a top tier may be electrically connected to the first source/drain pattern SD1 at a bottom tier.

Additional metal layers (e.g., M2, M3, M4, etc.) may be stacked on the first metal layer M1. The first metal layer M1 and metal layers (e.g., M2, M3, M4, etc.) on the first metal layer M1 may constitute a back-end-of-line (BEOL) layer of a semiconductor device. The metal layers (e.g., M2, M3, M4, etc.) on the first metal layer M1 may include routing lines for connecting logic cells to each other.

According to some example embodiments of the present inventive concepts, the first and second power lines POR1 and POR2 may not be provided in the first metal layer M1 of a back-end-of-line (BEOL) layer, but may be provided in the device isolation layer ST below a front-end-of-line (FEOL) layer. In addition, the power delivery network PDN that applies voltages to the first and second power lines POR1 and POR2 may not be provided in metal layers of a back-end-of-line (BEOL) layer, but may be provided below the substrate 100.

Because a semiconductor device according to the present inventive concepts has a three-dimensional cell structure as discussed with reference to FIG. 2, the semiconductor device according to the present inventive concepts may have a relatively small cell height HE2, compared to the two-dimensional cell structure of FIG. 1. According to some example embodiments, the first and second power lines POR1 and POR2 are omitted in the first metal layer M1, even when the logic cell LC has a relatively small cell height HE2, the first metal layer M1 may have therein a sufficient number of the wiring lines MI1 to MI4 for signal transfer. As a result, a semiconductor device according to the present inventive concepts may increase in integration and routing freedom.

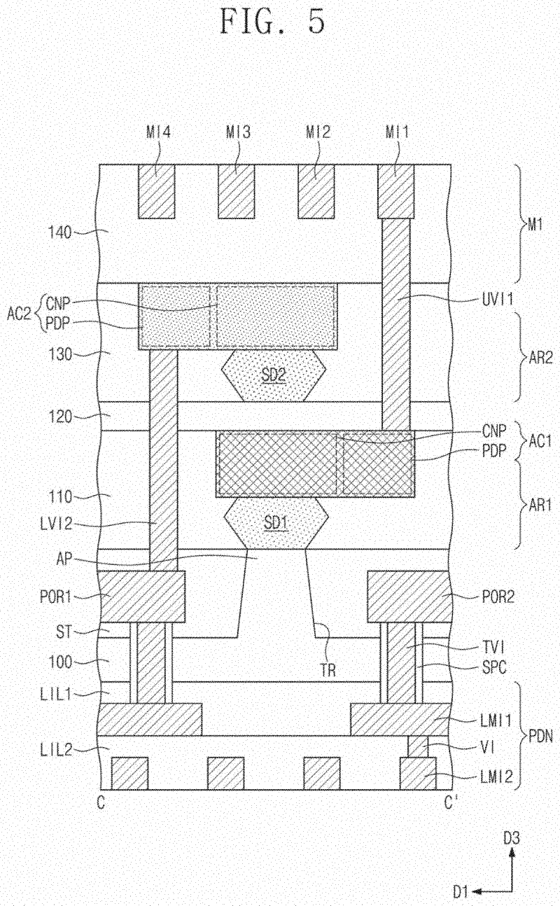

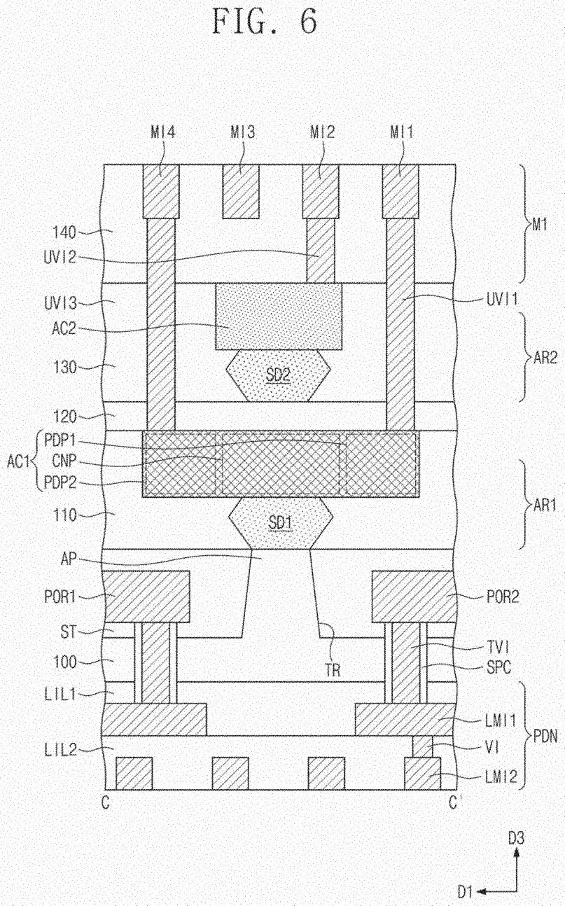

FIGS. 5 and 6 illustrate cross-sectional views taken along line C-C′ of FIG. 3, showing a semiconductor device according to some example embodiments of the present inventive concepts. In the example embodiments that follow, a detailed description of technical features repetitive to those discussed above with reference to FIGS. 3 and 4A to 4D will be omitted, and a difference thereof will be discussed in detail.

Referring to FIG. 5, the pad part PDP of the first active contact AC1 may be electrically connected through the first upper via UVI1 to the first wiring line MI1. The pad part PDP of the first active contact AC1 may not vertically overlap the second active contact AC2. When viewed in plan, the pad part PDP of the first active contact AC1 may be offset from the second active contact AC2. The first upper via UVI1 may be horizontally spaced apart from a sidewall of the second active contact AC2.

Referring to FIG. 6, the first active contact AC1 may include a first pad part PDP1 and a second pad part PDP2. The first and second pad parts PDP1 and PDP2 of the first active contact AC1 may be provided on opposite sides of the connection part CNP. Neither the first pad part PDP1 nor the second pad part PDP2 of the first active contact AC1 may vertically overlap the second active contact AC2.

The first pad part PDP1 of the first active contact AC1 may be electrically connected through the first upper via UVI1 to the first wiring line MI1. The second pad part PDP2 of the first active contact AC1 may be electrically connected through a third upper via UVI3 to the fourth wiring line MI4. The first upper via UVI1 and the third upper via UVI3 may be spaced apart from opposite sidewalls of the second active contact AC2. The second active contact AC2 may be electrically connected through the second upper via UVI2 to the second wiring line MI2.

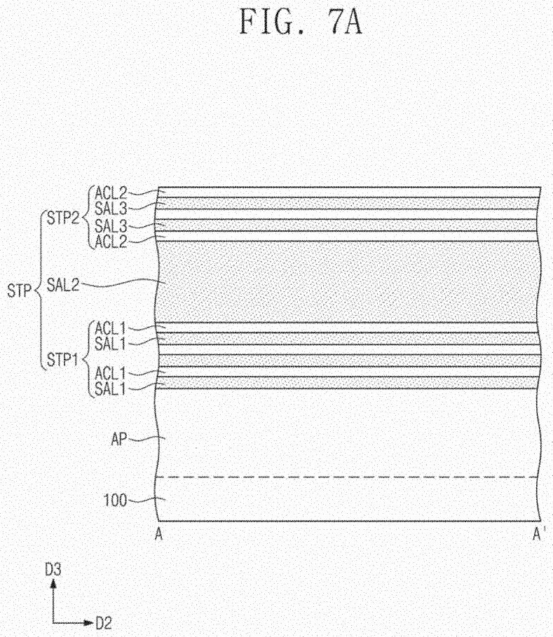

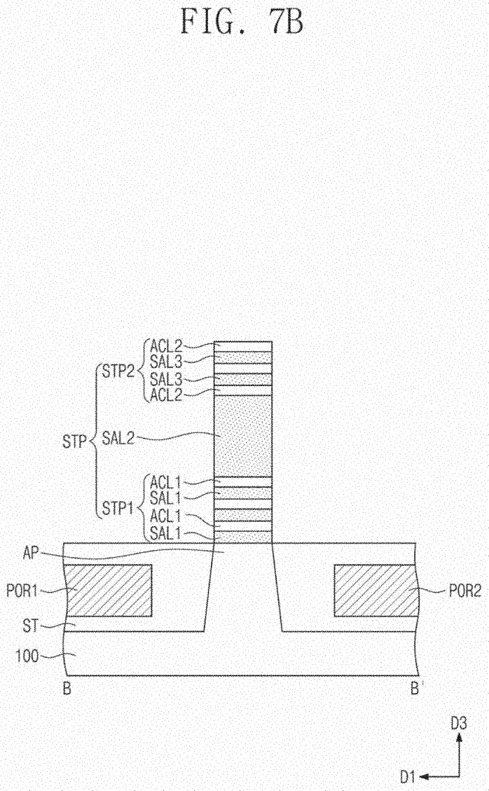

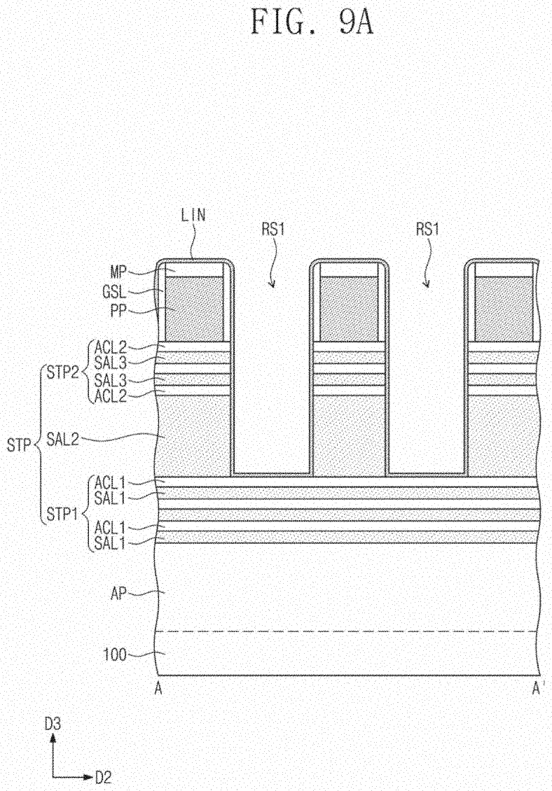

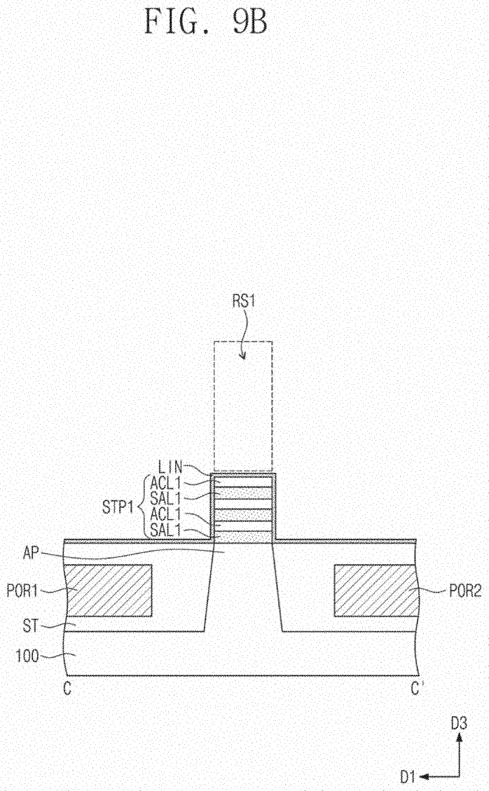

FIGS. 7A to 16C illustrate cross-sectional views showing a method of fabricating a semiconductor device according to some example embodiments of the present inventive concepts. FIGS. 7A, 8A, 9A, 10A, 11A, 12A, 13A, 14A, 15A, and 16A illustrate cross-sectional views taken along line A-A′ of FIG. 3. FIGS. 7B, 8B, 14B, 15B, and 16B illustrate cross-sectional views taken along line B-B′ of FIG. 3. FIGS. 9B, 10B, 11B, 12B, 13B, and 16C illustrate cross-sectional views taken along line C-C′ of FIG. 3.

Referring to FIGS. 7A and 7B, first sacrificial layers SAL1 and first active layers ACL1 may be alternately stacked on a substrate 100. The first sacrificial layers SAL1 may include one of silicon (Si), germanium (Ge), and silicon-germanium (SiGe), and the first active layers ACL1 may include another of silicon (Si), germanium (Ge), and silicon-germanium (SiGe). For example, the first sacrificial layers SAL1 may include silicon-germanium (SiGe), and the first active layers ACL1 may include silicon (Si). Each of the sacrificial layers SAL may have a germanium concentration of about or exactly 10 at % to about or exactly 30 at %.

A second sacrificial layer SAL2 may be formed on an uppermost first active layer ACL1. The second sacrificial layer SAL2 may have a thickness greater than that of the first active layer ACL1 and that of the first sacrificial layer SALT. The second sacrificial layer SAL2 may include the same material as that of the first sacrificial layer SALT.

Third sacrificial layers SAL3 and second active layers ACL2 may be alternately staked on the second sacrificial layer SAL2. Each of the third sacrificial layers SAL3 may include the same material as that of the first sacrificial layer SAL1, and each of the second active layers ACL2 may include the same material as that of the first active layer ACL1.

The first, second, and third sacrificial layers SAL1, SAL2, and SAL3 and the first and second active layers ACL1 and ACL2 may be patterned to form a stack pattern STP. The formation of the stack pattern STP may include forming a hardmask pattern on an uppermost second active layer ACL2, and using the hardmask pattern as an etching mask to etch the layers SAL1 to SAL3, ACL1, and ACL2 stacked on the substrate 100. During the formation of the stack pattern STP, an upper portion of the substrate 100 may be patterned to form a trench TR that defines an active pattern AP. The stack pattern STP may have a linear shape that extends in a second direction D2.

The stack pattern STP may include a first stack pattern STP1 on the active pattern AP, a second stack pattern STP2 on the first stack pattern STP1, and the second sacrificial layer SAL2 between the first and second stack patterns STP1 and STP2. The first stack pattern STP1 may include the first sacrificial layers SALT and the first active layer ACL1 that are alternately stacked. The second stack pattern STP2 may include the third sacrificial layers SAL3 and the second active layers ACL2 that are alternately stacked.

On the substrate 100, a device isolation layer ST may be formed to fill the trench TR. For example, a dielectric layer may be formed on an entire surface of the substrate 100, covering the active pattern AP and the stack pattern STP. The dielectric layer may be recessed to form the device isolation layer ST until the stack pattern STP is exposed.

The formation of the device isolation layer ST may include forming a first power line POR1 and a second power line POR2 that are embedded in the device isolation layer ST. The first power line POR1 and the second power line POR2 may have a linear shape that extends in the second direction D2.

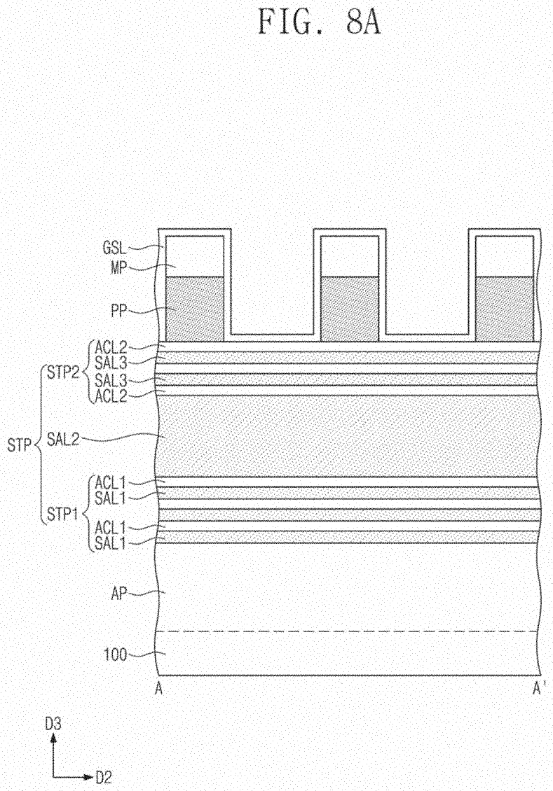

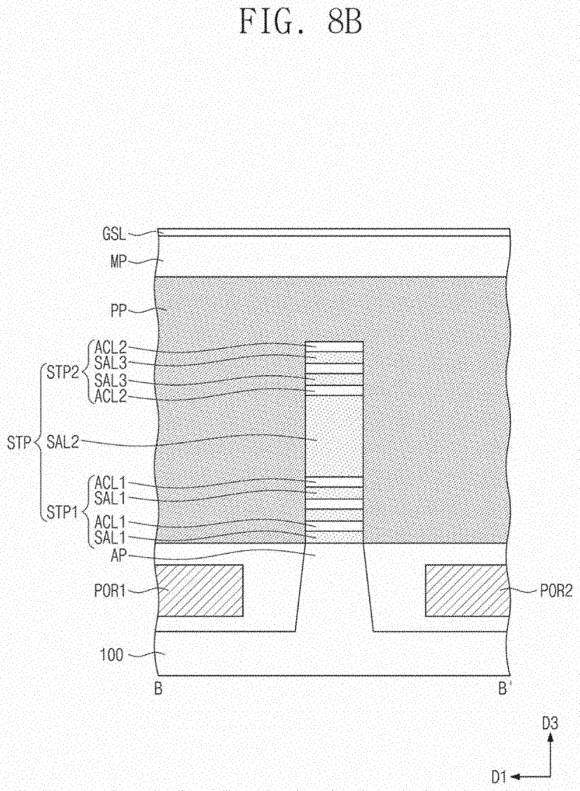

Referring to FIGS. 8A and 8B, sacrificial patterns PP may be formed to run across the stack pattern STP. Each of the sacrificial patterns PP may be formed to have a linear shape that extends in a first direction D1. The sacrificial patterns PP may be arranged at a first pitch along the second direction D2.

For example, the formation of the sacrificial patterns PP may include forming a sacrificial layer on the entire surface of the substrate 100, forming hardmask patterns MP on the sacrificial layer, and using the hardmask patterns MP as an etching mask to pattern the sacrificial layer. The sacrificial layer may include one or more of amorphous silicon and polysilicon.

A spacer layer GSL may be conformally formed on the entire surface of the substrate 100. The spacer layer GSL may cover the sacrificial patterns PP and the hardmask patterns MP. For example, the spacer layer GSL may include at least one selected from SiCN, SiCON, and SiN.

Referring to FIGS. 9A and 9B, the spacer layer GSL and the hardmask patterns MP may be used as an etching mask to perform a first etching process. The first etching process may form a first recess RS1 in the stack pattern STP between the sacrificial patterns PP. The first recess RS1 may be formed between a pair of sacrificial patterns PP.

The first etching process may be an anisotropic etching process. The first etching process may form the spacer layer GSL into a gate spacer GS that covers a sidewall of the sacrificial pattern PP. The first etching process may be performed until the uppermost first active layer ACL1 of the first stack pattern STP1 is exposed. For example, the first recess RS1 may expose the first stack pattern STP1.

A liner layer LIN may be conformally formed on the entire surface of the substrate 100. The liner layer LIN may cover the gate spacers GS and the hardmask patterns MP. The liner layer LIN may cover an inner wall of the first recess RS1. The liner layer LIN may cover the exposed first stack pattern STP1. For example, the liner layer LIN may include silicon nitride.

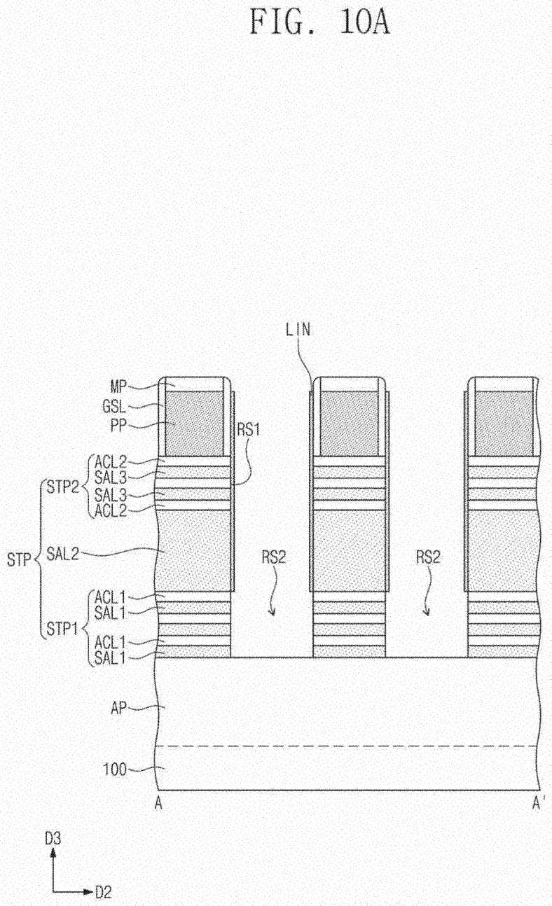

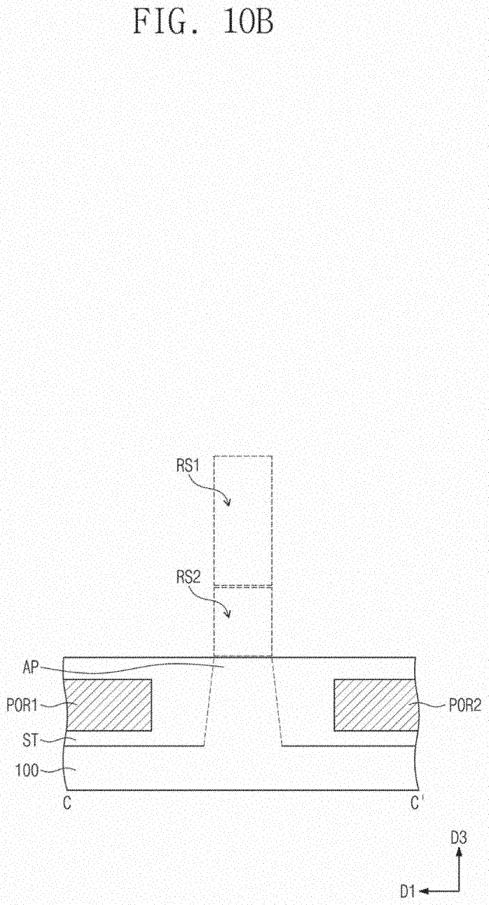

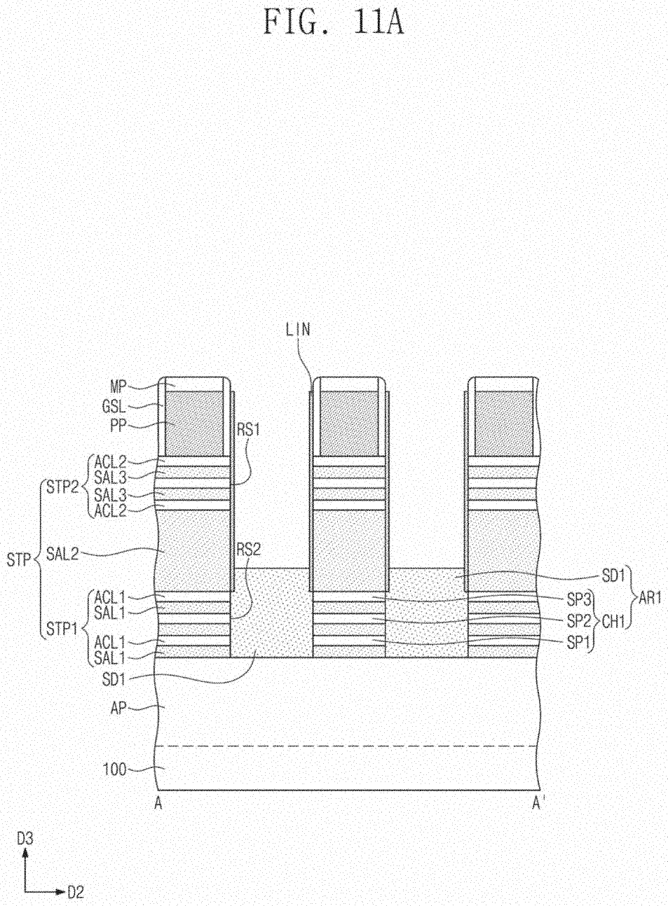

Referring to FIGS. 10A and 10B, the liner layer LIN, the gate spacers GS, and the hardmask patterns MP may be used as an etching mask to perform a second etching process on the stack pattern STP. In the second etching process, the first stack pattern STP1 between the sacrificial patterns PP may be removed to form a second recess RS2. The second recess RS2 may further extend downwardly from the first recess RS1.

The second etching process may be an anisotropic etching process. The second etching process may be carried out until a top surface of the active pattern AP is exposed. For example, the second recess RS2 may expose the top surface of the active pattern AP.

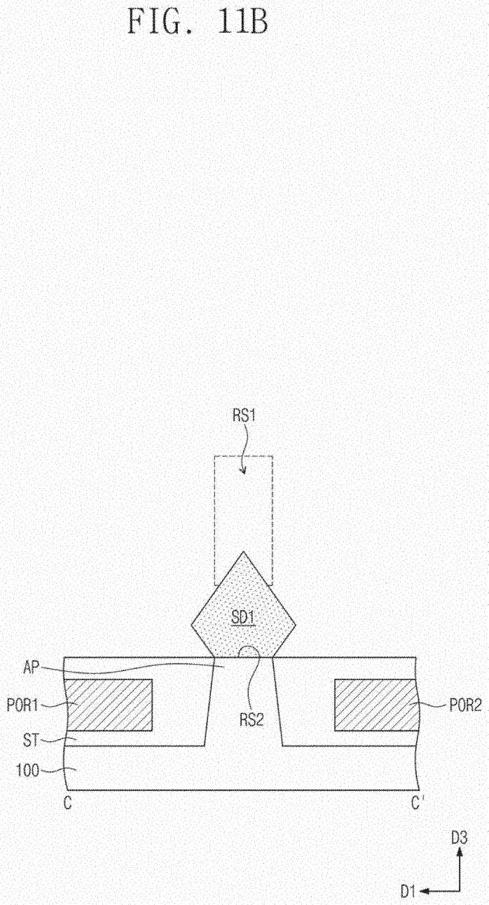

Referring to FIGS. 11A and 11B, first source/drain patterns SD1 may be formed in the second recesses RS2. For example, the first source/drain pattern SD1 may be formed by performing a first selective epitaxial growth (SEG) process in which an inner wall of the second recess RS2 is used as a seed layer. The first source/drain pattern SD1 may be grown from a seed, the substrate 100 and the first active layers ACL1, exposed to the second recess RS2. For example, the first SEG process may include chemical vapor deposition (CVD) or molecular beam epitaxy (MBE).

The first source/drain pattern SD1 may be in-situ doped with impurities during the first SEG process. Alternatively, after the first source/drain pattern SD1 is formed, impurities may be implanted into the first source/drain pattern SD1. The first source/drain pattern SD1 may be doped to have a first conductivity type.

A first channel pattern CH1 may be formed of the first active layers ACL1 interposed between a pair of first source/drain patterns SD1. For example, the first active layers ACL1 may constitute first, second, and third semiconductor patterns SP1, SP2, and SP3 of the first channel pattern CH1. The first channel patterns CH1 and the first source/drain patterns SD1 may form a first active region AR1 as a bottom tier of a three-dimensional device.

Because the liner layer LIN covers the inner wall of the first recess RS1, no semiconductor layer may be separately formed in the first recess RS1 during the first SEG process.

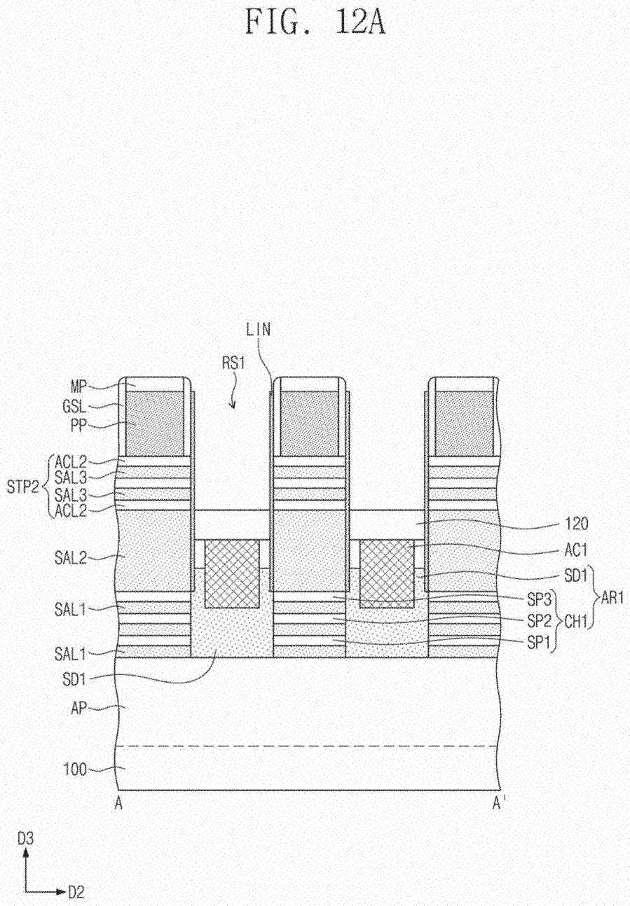

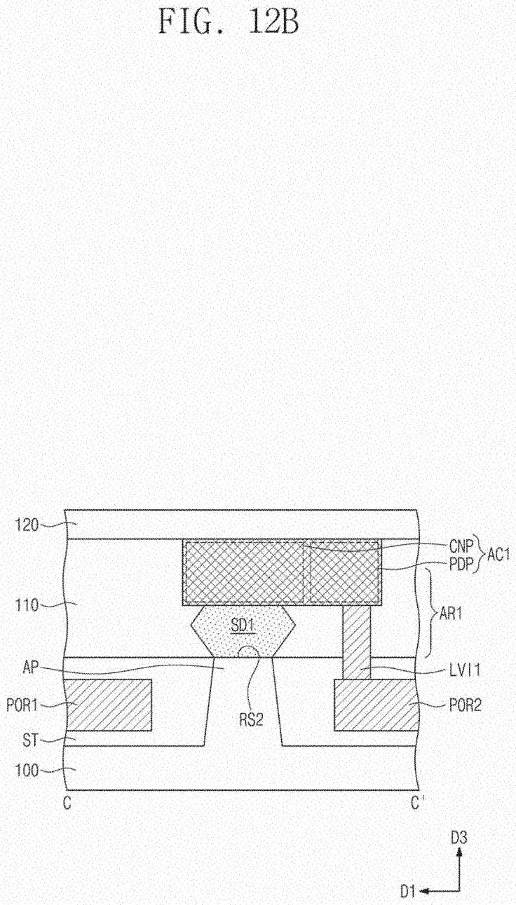

Referring to FIGS. 12A and 12B, a first interlayer dielectric layer 110 may be formed to cover the first source/drain patterns SD1. The first interlayer dielectric layer 110 may be recessed to have a top surface lower than that of the second sacrificial layer SAL2.

Active contacts AC may be formed in the first interlayer dielectric layer 110 to be coupled to the first source/drain patterns SD1. For example, at least one first active contact AC1 may include a connection part CNP coupled to the first source/drain pattern SD1 and a pad part PDP that horizontally extends from the connection part CNP.

A first lower via LVI1 coupled to the second power line POR2 may be formed below the pad part PDP of the first active contact AC1. For example, the first lower via LVI1 may be formed prior to the formation of the first active contact AC1. For another example, the first lower via LVI1 and the first active contact AC1 may be concurrently formed in a dual damascene process.

A second interlayer dielectric layer 120 may be formed on the first interlayer dielectric layer 110. The second interlayer dielectric layer 120 may be formed to have a top surface coplanar with that of the second sacrificial layer SAL2.

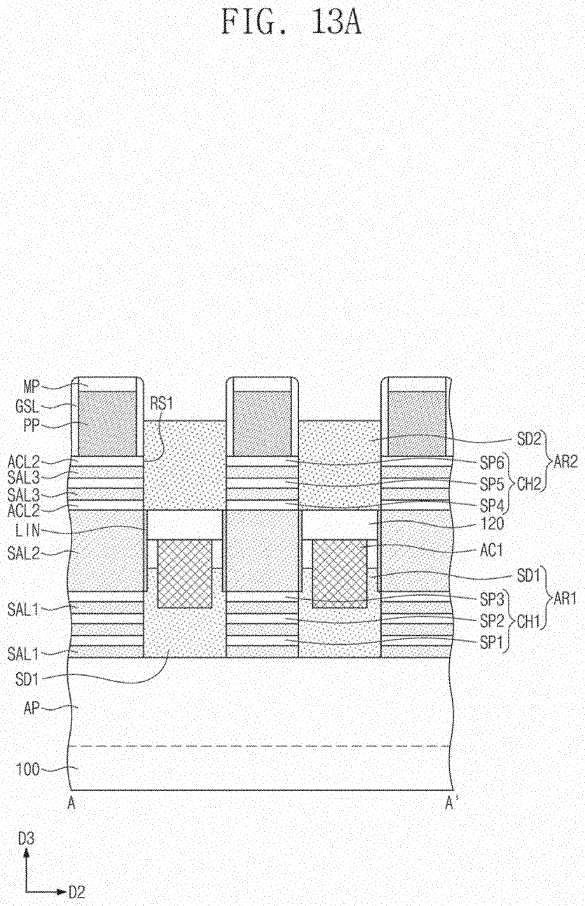

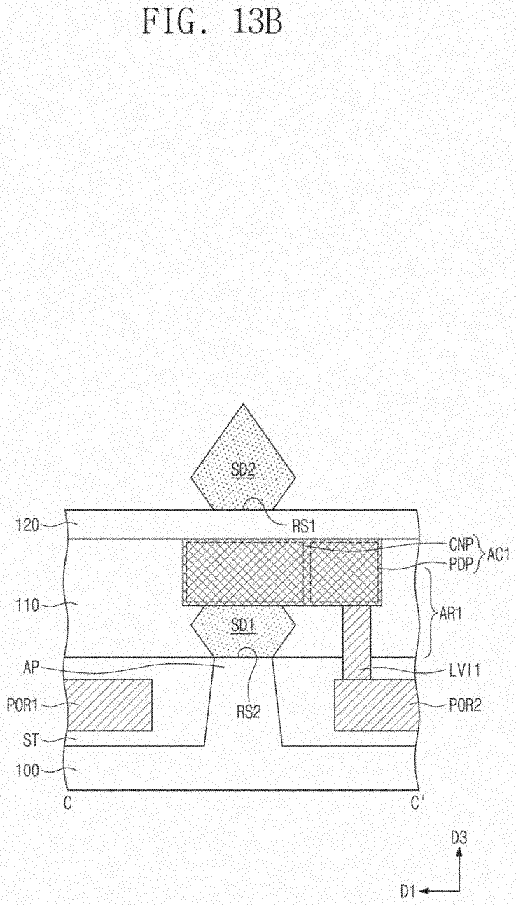

Referring to FIGS. 13A and 13B, the liner layer LIN may be partially removed which is exposed to the first recess RS1. A remaining liner layer LIN may cover a sidewall of the second sacrificial layer SAL2.

Second source/drain patterns SD2 may be correspondingly formed in the second recesses RS2. For example, the second source/drain pattern SD2 may be formed by performing a second SEG process in which the inner wall of the first recess RS1 is used as a seed layer. The second source/drain pattern SD2 may be grown from a seed or the second active layers ACL2 exposed to the first recess RS1. The second source/drain patterns SD2 may be doped to have a second conductivity type different from the first conductivity type.

A second channel pattern CH2 may be formed of the second active layers ACL2 interposed between a pair of second source/drain patterns SD2. For example, the second active layers ACL2 may constitute fourth, fifth, and sixth semiconductor patterns SP4, SP5, and SP6 of the second channel pattern CH2. The second channel patterns CH2 and the second source/drain patterns SD2 may form a second active region AR2 as a top tier of a three-dimensional device.

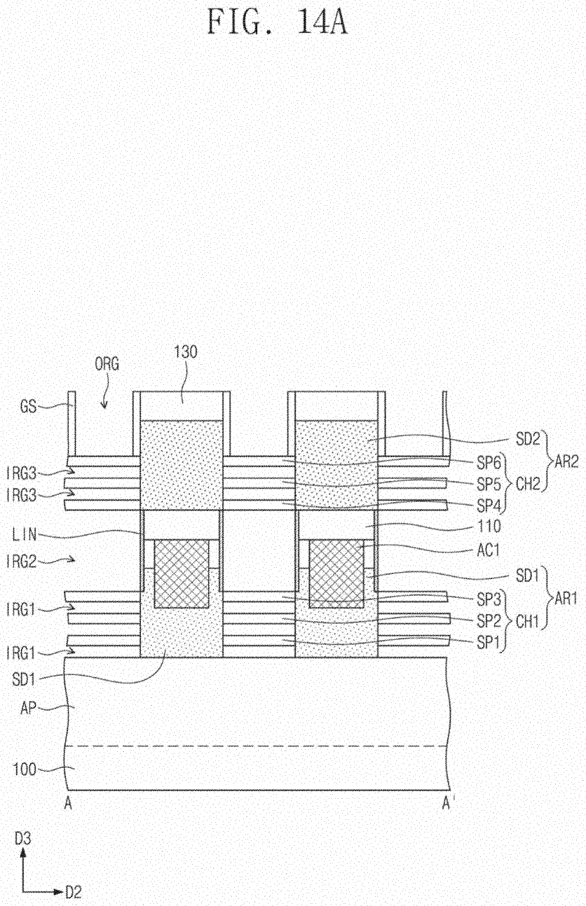

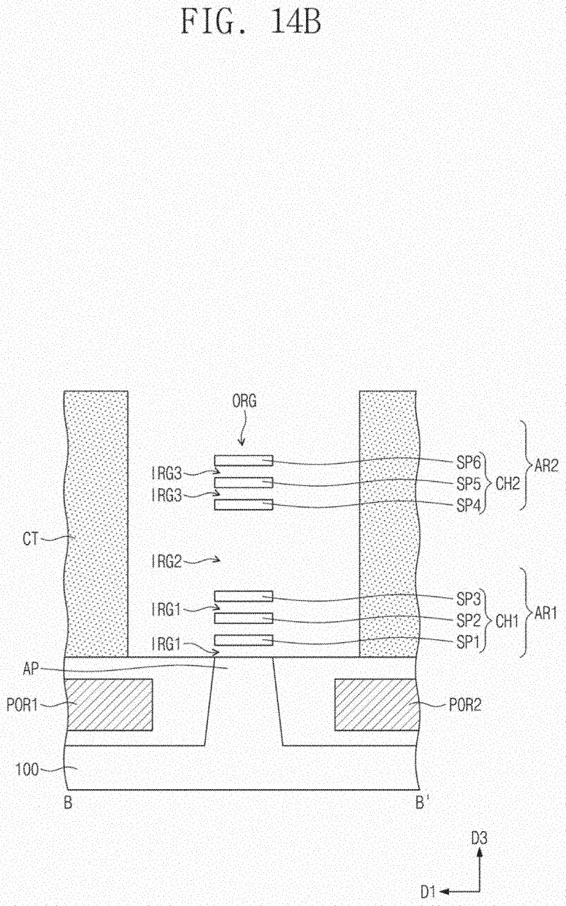

Referring to FIGS. 14A and 14B, a third interlayer dielectric layer 130 may be formed to cover the hardmask patterns MP, the gate spacers GS, and the second source/drain patterns SD2. For example, the third interlayer dielectric layer 130 may include a silicon oxide layer.

A planarization process may be performed such that the third interlayer dielectric layer 130 may be planarized until top surfaces of the sacrificial patterns PP are exposed. An etch-back or chemical mechanical polishing (CMP) process may be employed to planarize the third interlayer dielectric layer 130. The hardmask patterns MP may all be removed during the planarization process. As a result, the third interlayer dielectric layer 130 may have a top surface coplanar with those of the sacrificial patterns PP and those of the gate spacers GS.

Gate cutting patterns CT may be formed to penetrate the sacrificial patterns PP. The gate cutting patterns CT may be formed on the first and second cell boundaries CB1 and CB2 of the logic cell LC (see FIG. 3). The gate cutting patterns CT may include one or more of a silicon oxide layer and a silicon nitride layer.

The exposed sacrificial patterns PP may be selectively removed. The removal of the sacrificial patterns PP may form an outer region ORG that exposes the first and second channel patterns CH1 and CH2 (see FIG. 14B). The removal of the sacrificial patterns PP may include performing a wet etching process that uses an etchant capable of selectively etching polysilicon.

The first, second, and third sacrificial layers SAL1, SAL2, and SAL3 exposed to the outer region ORG may be selectively removed to respectively form first, second, and third inner regions IRG1, IRG2, and IRG3 (see FIG. 14B). For example, an etching process may be performed in which the first, second, and third sacrificial layers SAL1, SAL2, and SAL3 are selectively etched, such that the first, second, and third sacrificial layers SAL1, SAL2, and SAL3 may be removed but the first to sixth semiconductor patterns SP1 to SP6 may be left. The etching process may have an excellent etch selectivity with respect to silicon-germanium whose germanium concentration is relatively high. For example, the etching process may have a high etch rate with respect to silicon-germanium whose germanium concentration is greater than about or exactly 10 at %.

The selective removal of the first, second, and third sacrificial layers SAL1, SAL2, and SAL3 may cause the first, second, and third semiconductor patterns SP1, SP2, and SP3 to remain on the first active region AR1, and may also cause the fourth, fifth, and sixth semiconductor patterns SP4, SP5, and SP6 to remain on the second active region AR2. The first inner regions IRG1 may be defined to indicate empty spaces between the first, second, and third semiconductor patterns SP1, SP2, and SP3 of the first active region AR1. The third inner regions IRG3 may be defined to indicate empty spaces between the fourth, fifth, and sixth semiconductor patterns SP4, SP5, and SP6 of the second active region AR2. The second inner region IRG2 may be defined to indicate an empty space between the first active region AR1 and the second active region AR2.

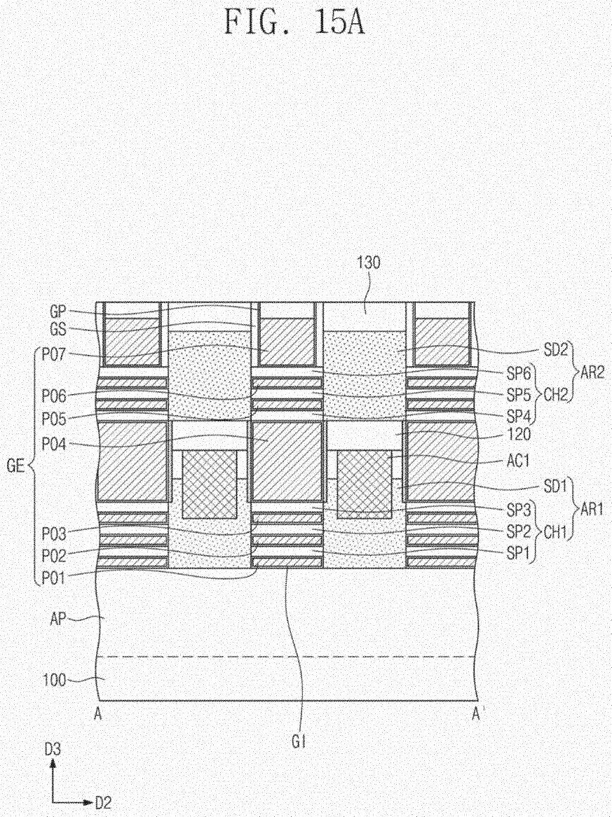

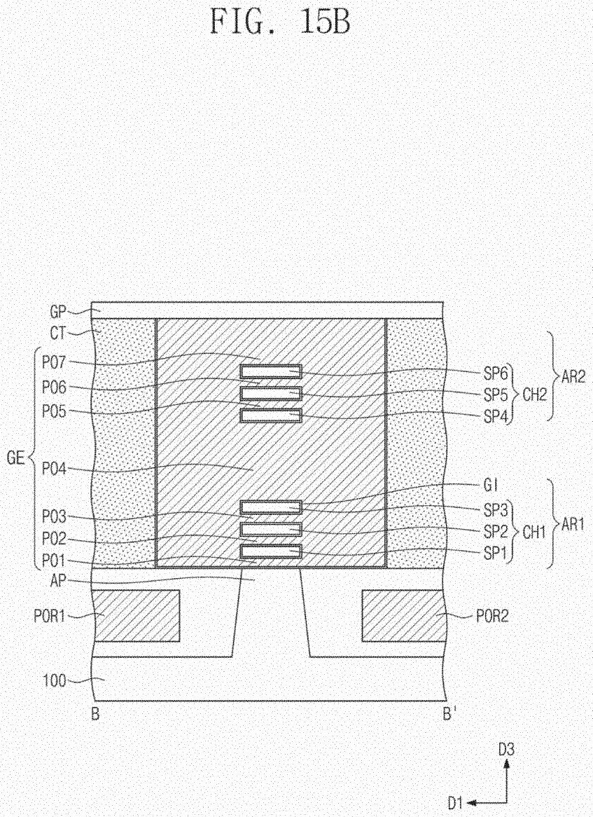

Referring to FIGS. 15A and 15B, a gate dielectric layer GI may be conformally formed on the exposed first to sixth semiconductor patterns SP1 to SP6. A gate electrode GE may be formed on the gate dielectric layer GI. The gate electrode GE may include first to sixth parts PO1 to PO6 formed in the first, second, and third inner regions IRG1, IRG2, and IRG3. The gate electrode GE may further include a seventh part PO7 formed in the outer region ORG.

The gate electrode GE may be recessed to have a reduced height. A gate capping pattern GP may be formed on the recessed gate electrode GE. The gate capping pattern GP may undergo a planarization process to allow the gate capping pattern GP to have a top surface coplanar with that of the third interlayer dielectric layer 130.

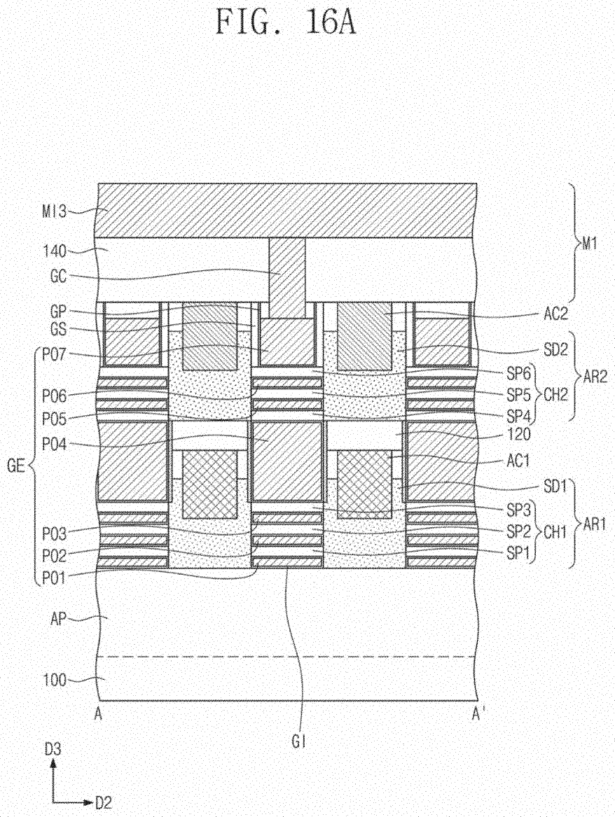

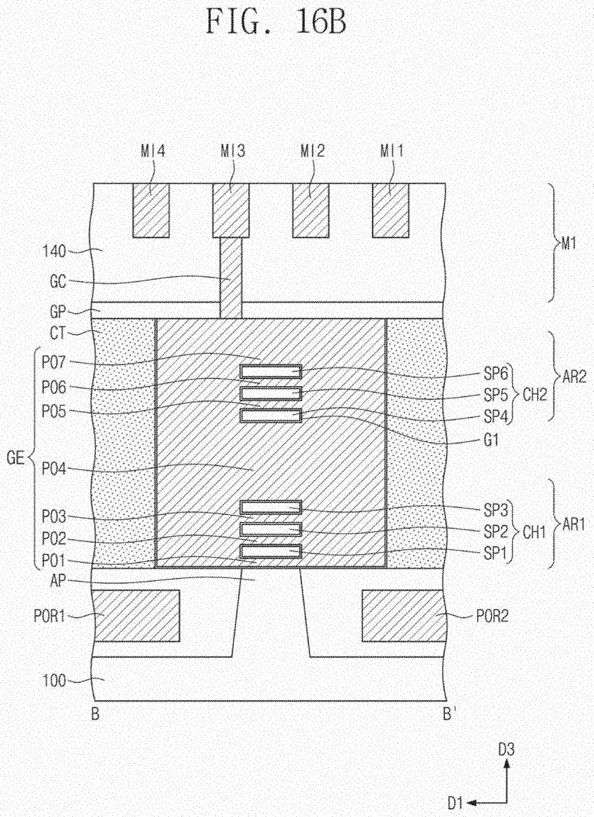

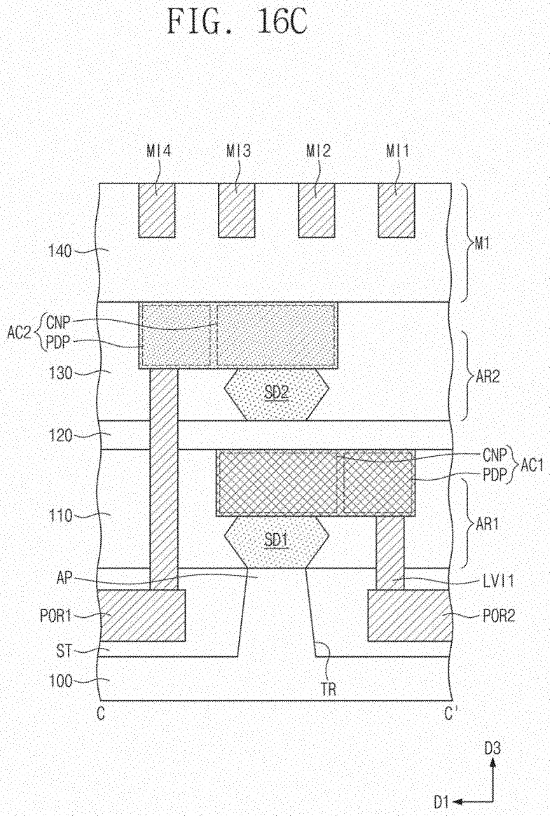

Referring to FIGS. 16A to 16C, second active contacts AC2 may be formed to be coupled to the second source/drain patterns SD2 in the third interlayer dielectric layer 130. For example, at least one second active contact AC2 may include a connection part CNP coupled to the second source/drain pattern SD2 and a pad part PDP that horizontally extends from the connection part CNP.

A second lower via LVI2 coupled to the first power line POR1 may be formed below the pad part PDP of the second active contact AC2. For example, the second lower via LVI2 may be formed prior the formation of the second active contact AC2. For another example, the second lower via LVI2 and the second active contact AC2 may be concurrently formed in a dual damascene process.

A fourth interlayer dielectric layer 140 may be formed on the third interlayer dielectric layer 130. A first metal layer M1 may be formed in the fourth interlayer dielectric layer 140. The formation of the first metal layer M1 may include forming first to fourth wiring lines MI1 to MI4 on an upper portion of the fourth interlayer dielectric layer 140.

A gate contact GC may be formed to connect the gate electrode GE to the first metal layer M1. First and second upper vias UVI1 and UVI2 may be formed to connect the first and second active contacts AC1 and AC2 to the first metal layer M1 (see FIG. 4D). For example, the gate contact GC and the first and second upper vias UVI1 and UVI2 may be formed prior to the formation of the first to fourth wiring lines MI1 to MI4. For another example, a dual damascene process may be performed to concurrently form the gate contact GC, the first and second upper vias UVI1 and UVI2, and the first to fourth wiring lines MI1 to MI4.

Although not shown, additional metal layers (e.g., M2, M3, M4, etc.) may be formed on the first metal layer M1. The first metal layer M1 and metal layers (e.g., M2, M3, M4, etc.) on the first metal layer M1 may constitute a back-end-of-line (BEOL) layer of a semiconductor device.

Referring back to FIGS. 3 and 4A to 4D, a power delivery network PDN may be formed on a bottom surface of the substrate 100. For example, a first lower dielectric layer LIL1 may be formed on the bottom surface of the substrate 100. Through vias TVI may be formed to penetrate the first lower dielectric layer LIL1 and the substrate 100, thereby being coupled to the first and second power lines POR1 and POR2. First lower lines LMI1 may be formed on the through vias TVI. A second lower dielectric layer LIL2 and second lower lines LMI2 may be formed on the first lower dielectric layer LIL1.

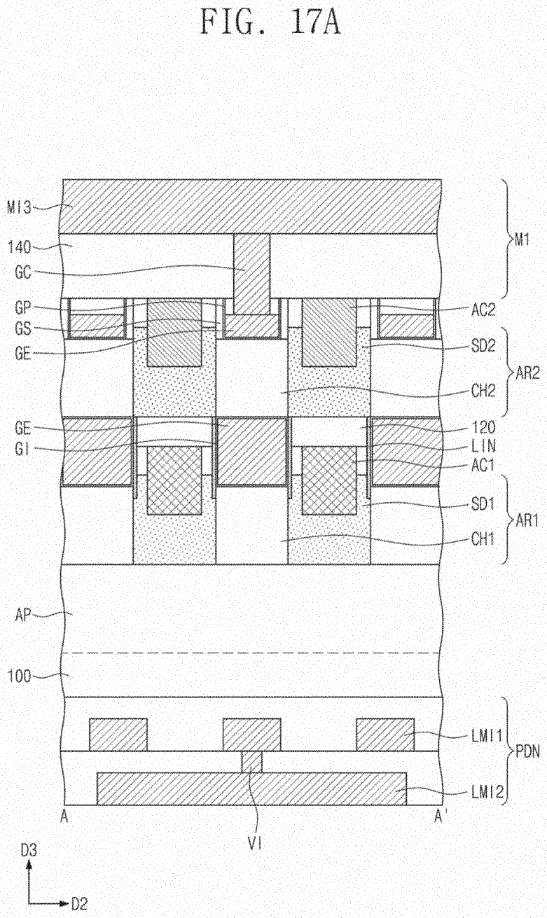

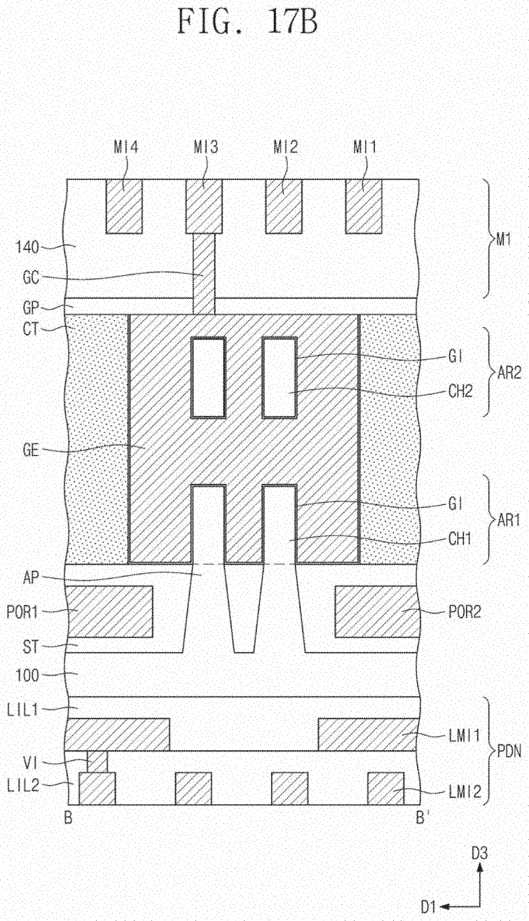

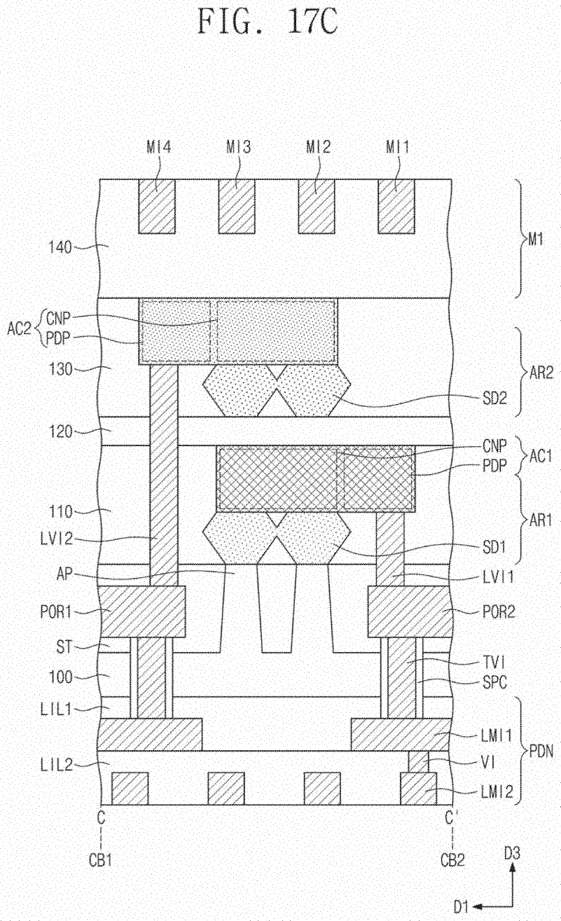

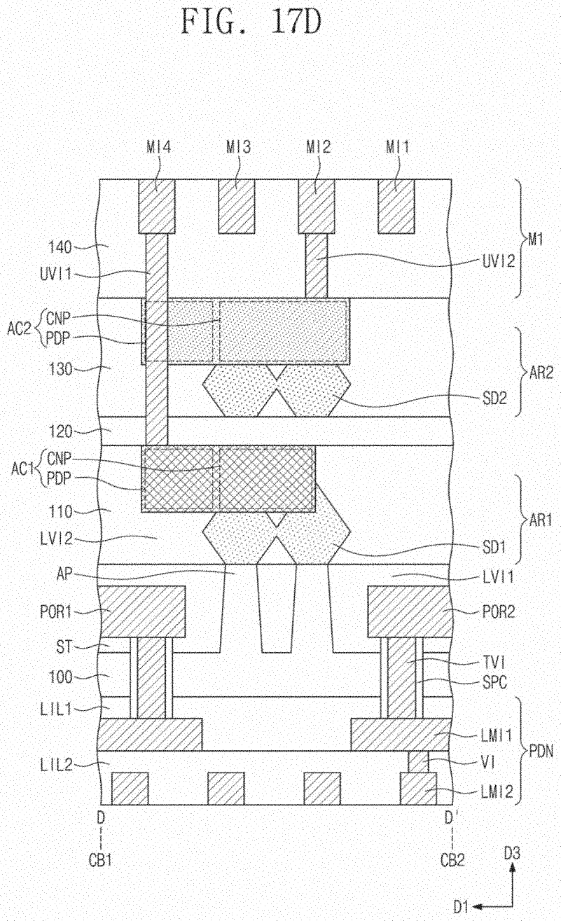

FIGS. 17A, 17B, 17C, and 17D illustrate cross-sectional views respectively taken along lines A-A′, B-B′, C-C′, and D-D′ of FIG. 3, showing a semiconductor device according to some example embodiments of the present inventive concepts. In some of the example embodiments that follow, a detailed description of technical features repetitive to those discussed above with reference to FIGS. 3 and 4A to 4D will be omitted, and a difference thereof will be discussed in detail.

Referring to FIGS. 3 and 17A to 17D, the device isolation layer ST may define a plurality of active patterns AP on an upper portion of the substrate 100. The device isolation layer ST may cover a lower sidewall of each of the active patterns AP. An upper portion of each of the active patterns AP may protrude upwardly from the device isolation layer ST (see FIG. 17B).

Each of the active patterns AP may include, on its upper portion, first source/drain patterns SD1 and a first channel pattern CH1 between the first source/drain patterns SD1. The first channel pattern CH1 may not include any of the first, second, and third semiconductor patterns SP1, SP2, and SP3 that are stacked as discussed above with reference to FIGS. 4A to 4D. The first channel pattern CH1 may have a semiconductor pillar shape that protrudes upwardly from the device isolation layer ST.

The second active region AR2 may include second source/drain patterns SD2 and a second channel pattern CH2 between the second source/drain patterns SD2. The second channel pattern CH2 may not include any of the fourth, fifth, and sixth semiconductor patterns SP4, SP5, and SP6 that are stacked as discussed above with reference to FIGS. 4A to 4D. The second channel pattern CH2 may have a semiconductor pillar shape.

The gate electrode GE may be provided on a top surface and opposite sidewalls of the first channel pattern CH1. The gate electrode GE may surround the second channel pattern CH2. A transistor according to some example embodiments may include a fin-shaped channel. A transistor according to some example embodiments may be a three-dimensional field effect transistor (e.g., FinFET) in which the gate electrode GE three-dimensionally surrounds the first and second channel patterns CH1 and CH2.

Referring back to FIG. 17C, the first source/drain patterns SD1 may be provided o corresponding active patterns AP. For example, neighboring first source/drain patterns SD1 may be merged to constitute a single first source/drain pattern SD1. Neighboring second source/drain patterns SD2 may also be merged to constitute a single second source/drain pattern SD2.

In addition, a detailed description of the first and second active contacts AC1 and AC2, the gate contact GC, the first metal layer M1, and the power delivery network PDN may be substantially the same as that discussed above with reference to FIGS. 3 and 4A to 4D.

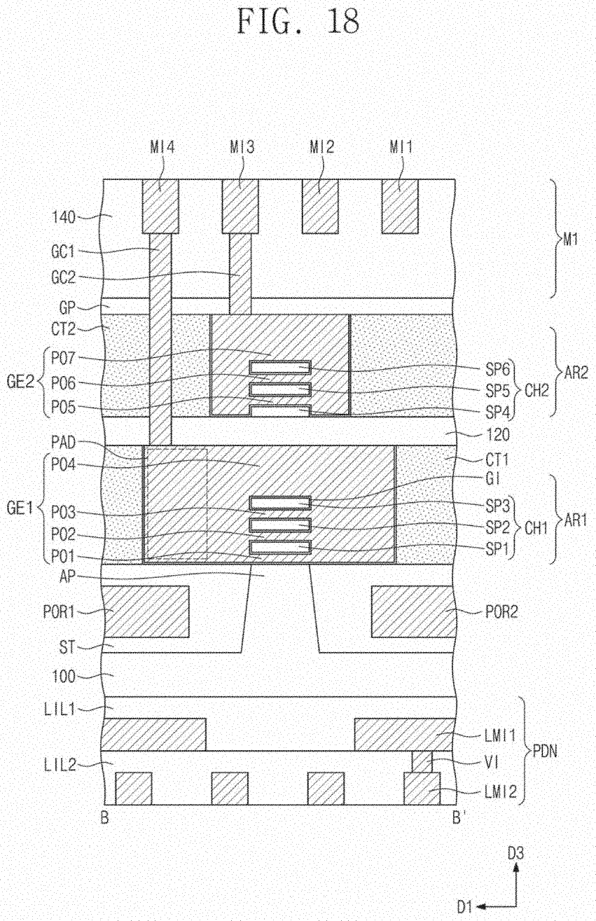

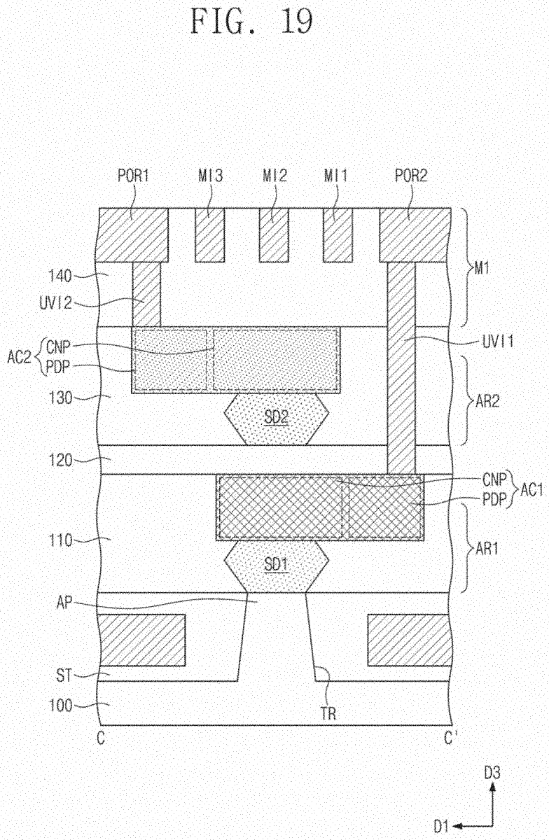

FIG. 18 illustrates a cross-sectional view taken along line B-B of FIG. 3, showing a semiconductor device according to some example embodiments of the present inventive concepts. FIG. 19 illustrates a cross-sectional view taken along line C-C′ of FIG. 3, showing a semiconductor device according to some example embodiments of the present inventive concepts. In the example embodiments that follow, a detailed description of technical features repetitive to those discussed above with reference to FIGS. 3 and 4A to 4D will be omitted, and a difference thereof will be discussed in detail.

Referring to FIG. 18, the gate electrode GE may include a first gate electrode GE1 located at the same level as that of the first active region AR1 and a second gate electrode GE2 located at the same level as that of the second active region AR2. The second interlayer dielectric layer 120 may separate the first gate electrode GE1 and the second gate electrode GE2 from each other in the third direction D3.

The first gate electrode GE1 may include first, second, third, and fourth parts PO1, PO2, PO3, and PO4 that surround the first, second, and third semiconductor patterns SP1, SP2, and SP3. The second gate electrode GE2 may include fifth, sixth, and seventh parts PO5, PO6, and PO7 that surround the fourth, fifth, and sixth semiconductor patterns SP4, SP5, and SP6.

First gate cutting patterns CT1 may be provided on opposite ends of the first gate electrode GE1. Second gate cutting patterns CT2 may be provided on opposite ends of the second gate electrodes GE2. A length in the first direction D1 of the first gate cutting pattern CT1 may be less than a length in the first direction D1 of the second gate cutting pattern CT2.

The first gate electrode GE1 may further include a pad part PAD. The pad part PAD of the first gate electrode GE1 may not vertically overlap the second gate electrode GE2. When viewed in plan, the pad part PAD of the first gate electrode GE1 may be horizontally offset from the second gate electrode GE2.

A first gate contact GC1 may be provided on a top surface of the pad part PAD included in the first gate electrode GE1. The first gate electrode GE1 may be electrically connected through the first gate contact GC1 to the fourth wiring line MI4. A second gate contact GC2 may be provided on a top surface of the second gate electrode GE2. The second gate electrode GE2 may be electrically connected through the second gate contact GC2 to the third wiring line MI3.

Referring to FIG. 19, the power delivery network PDN may be omitted from the bottom surface of the substrate 100. The first and second power lines POR1 and POR2 may be provided in the first metal layer M1.

The first active contact AC1 may be connected through the first upper via UVI1 to the second power line POR2. The first upper via UVI1 may be provided between the second power line POR2 and the pad part PAD of the first active contact AC1. The first upper via UVI1 may be spaced apart from a sidewall of the second active contact AC2.

The second active contact AC2 may be connected through the second upper via UVI2 to the first power line POR1. The second upper via UVI2 may be provided between the first power line POR1 and the pad part PAD of the second active contact AC2.

A three-dimensional semiconductor device according to the present inventive concepts may be configured such that a PMOSFET region and an NMOSFET region are not two-dimensionally horizontally disposed, but three-dimensionally vertically stacked, which may result in a reduction in cell height of a logic cell. It therefore may be possible to increase device integration. In addition, according to the present inventive concepts, a first active contact and a second active contact may be disposed offset from each other, and a power line may be disposed not in a back-end-of-line (BEOL) layer, but below a front-end-of-line (FEOL) layer. Therefore, the degree of routing freedom may be obtained.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Although the present inventive concepts have been described in connection with some example embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A three-dimensional semiconductor device, comprising:
a first active region on a substrate, the first active region including a first source/drain pattern and a first channel pattern connected to the first source/drain pattern;
a first active contact on the first source/drain pattern;
a second active region on the first active region and the first active contact, the second active region including a second source/drain pattern and a second channel pattern connected to the second source/drain pattern;
a second active contact on the second source/drain pattern;
a gate electrode that vertically extends from the first channel pattern toward the second channel pattern;
a first power line and a second power line that are below the first active region; and
a first metal layer on the gate electrode and the second active contact,
the first active contact including
a first connection part connected to the first source/drain pattern; and
a first pad part that horizontally extends from the first connection part,
the second active contact including
a second connection part connected to the second source/drain pattern; and
a second pad part that horizontally extends from the second connection part,
the first pad part being horizontally offset from the second active contact,
the second pad part being horizontally offset from the first active contact,
the first pad part being electrically connected through a first via to one of the first power line and a first wiring line in the first metal layer, and
the second pad part being electrically connected through a second via to one of the second power line and a second wiring line in the first metal layer.

2. The device of claim 1, wherein the first connection part and the second connection part vertically overlap each other.

3. The device of claim 2, wherein
the first source/drain pattern vertically overlaps the first connection part, and
the second source/drain pattern vertically overlaps the second connection part.

4. The device of claim 1, wherein
the first via is electrically connected to the first wiring line, and
the first via is spaced apart from a sidewall of the second active contact.

5. The device of claim 1, wherein
the second via is electrically connected to the second power line, and
the second via is spaced apart from a sidewall of the first active contact.

6. The device of claim 1, wherein
the first active region is one of a PMOSFET region and an NMOSFET region, and
the second active region is the other of a PMOSFET region and an NMOSFET region.

7. The device of claim 1, further comprising:
a first gate cutting pattern and a second gate cutting pattern on opposite ends of the gate electrode,
wherein the first and second gate cutting patterns vertically overlap the first and second power lines.

8. The device of claim 1, further comprising:
a power delivery network on a bottom surface of the substrate; and
a plurality of through vias that electrically connect the first and second power lines to the power delivery network.

9. The device of claim 1, wherein
at least a portion of the first via vertically overlaps the first wiring line, and
at least a portion of the second via vertically overlaps the second wiring line.

10. The device of claim 1, wherein
the first active contact further includes a third pad part that stands opposite to the first pad part,
the third pad part is horizontally offset from the second active contact, and
the third pad part is electrically connected through a third via to a third wiring line in the first metal layer.

11. A three-dimensional semiconductor device, comprising:
a first active region on a substrate, the first active region including a first source/drain pattern and a first channel pattern connected to the first source/drain pattern;
a first active contact on the first source/drain pattern;
a second active region on the first active region and the first active contact, the second active region including a second source/drain pattern and a second channel pattern connected to the second source/drain pattern;
a second active contact on the second source/drain pattern, the second active contact including a first part that vertically overlaps the first active contact and a second part that does not vertically overlap the first active contact;
a gate electrode that vertically extends from the first channel pattern toward the second channel pattern;
a power line below the first active region;
a first metal layer on the gate electrode and the second active contact; and
a lower via on a bottom surface of the second part, the lower via electrically connecting the second part to the power line, the lower via being spaced apart from a sidewall of the first active contact.

12. The device of claim 11, wherein
the first active region is one of a PMOSFET region and an NMOSFET region, and
the second active region is the other of a PMOSFET region and an NMOSFET region.

13. The device of claim 11, further comprising:
an upper via on the first active contact, the upper via electrically connecting the first active contact to a wiring line of the first metal layer,
wherein the first active contact includes
a third part that vertically overlaps the second active contact; and
a fourth part that does not vertically overlap the second active contact,
wherein the upper via is on a top surface of the fourth part, and
wherein the upper via is spaced apart from a sidewall of the second active contact.

14. The device of claim 13, wherein the lower via and the upper via are opposite to each other across the first and second source/drain patterns.

15. The device of claim 11, further comprising:
a device isolation layer between the substrate and the first active region,
wherein the power line is buried in the device isolation layer.

16. A three-dimensional semiconductor device, comprising:
a device isolation layer on a substrate;
a first power line and a second power line that are buried in the device isolation layer;
a first active region on the device isolation layer, the first active region including a first source/drain pattern and a first channel pattern connected to the first source/drain pattern;
a first active contact on the first source/drain pattern;
a second active region on the first active region and the first active contact, the second active region including a second source/drain pattern and a second channel pattern connected to the second source/drain pattern;
a second active contact on the second source/drain pattern;
a gate electrode that vertically extends from the first channel pattern toward the second channel pattern;
a first gate cutting pattern and a second gate cutting pattern on opposite ends of the gate electrode; and
a first metal layer on the gate electrode and the second active contact,
wherein the first and second gate cutting patterns vertically overlap the first and second power lines.

17. The device of claim 16, wherein a pitch between the first and second power lines is a cell height of a logic cell.

18. The device of claim 16, wherein
the first active contact and the second active contact are offset from each other, and
at least a portion of the first active contact vertically overlaps at least a portion of the second active contact.

19. The device of claim 16, wherein
the first active contact is electrically connected through a first via to one of the first power line and a first wiring line in the first metal layer,
the second active contact is electrically connected through a second via to one of the second power line and a second wiring line in the first metal layer, and
the gate electrode is electrically connected through a gate contact to a third wiring line in the first metal layer.

20. The device of claim 16, further comprising:
a power delivery network on a bottom surface of the substrate; and
a plurality of through vias that electrically connect the first and second power lines to the power delivery network.
